(19) United States
(12) Patent Application Publication
(10) Pub. No.: US 2026/0239610 A1
(43) Pub. Date: Aug. 13, 2026

(54) SEMICONDUCTOR MEMORY DEVICE

(71) Applicant: Samsung Electronics Co., Ltd., Suwon-si (KR)

(72) Inventors: Hosang LEE, Suwon-si (KR); TAEJIN PARK, Suwon-si (KR); EuiJoong SHIN, Suwon-si (KR); Hyeon-Kyu LEE, Suwon-si (KR)

(21) Appl. No.: 19/274,700

(22) Filed: Jul. 21, 2025

(30) Foreign Application Priority Data
Feb. 7, 2025 (KR) 10-2025-0015995

(51) Int. Cl. H10B 12/00

(52) U.S. Cl. CPC H10B 12/50; H10B 12/09; H10B 12/315

(57) ABSTRACT

A semiconductor memory device including a substrate comprising a cell region and a connection region, a bit line on the substrate extending in a first direction across the cell region and the connection region, a word line on the cell region above the bit line and extending in a second direction, an active pattern on one side surface of the word line on the cell region, and a cell region isolation layer on the bit line on the connection region. The active pattern is an outermost active pattern, the cell region isolation layer includes a first insulating film on an outer side surface of the outermost active pattern and a second insulating film including a first portion and a second portion, wherein a lower surface of the second portion contacts an upper surface of the bit line.

### CROSS-REFERENCE TO RELATED APPLICATION

This application claims priority to and benefit of Korean Patent Application No. 10-2025-0015995, filed in the Korean Intellectual Property Office on Feb. 7, 2025, the entire contents of which are hereby incorporated by reference.

### BACKGROUND OF THE INVENTION

### Field of the Inventions

The present disclosure relates to semiconductor memory devices.

### Description of Related Art

A semiconductor device refers to a core component used in an electronic device to control or amplify an electric signal, and various types of semiconductor devices may be manufactured. For example, a semiconductor memory device is primarily used to store and retrieve data. The semiconductor memory device is a core element of an electronic device performing an indispensable role in various fields such as computers, communication equipment, and consumer electronics.

As industries develop, performance and functionality requirements for electronic devices are increasing. Therefore, for semiconductor memory devices to have high performance, the integration density of semiconductor memory devices is continuously increasing. During this development process, novel transistor structures such as transistors having vertical channels or vertical stack transistors have been proposed.

The information herein is provided to help understanding of the background of the present disclosure and may include information that does not correspond to the related art.

### SUMMARY OF THE INVENTION

An objective that the present disclosure aims to address is to provide a semiconductor memory device with improved electrical characteristics and/or reliability.

According to some embodiments of the present disclosure, a semiconductor memory device may include a substrate having a cell region and a connection region at one side of the cell region, a bit line on the substrate and extending in a first direction across the cell region and the connection region, a word line on the cell region above the bit line and extending in a second direction intersecting the first direction, a first active pattern disposed on one side surface of the word line on the cell region, and a cell region isolation layer on the bit line on the connection region. The first active pattern may be an outermost active pattern disposed at an outermost side of the cell region in the first direction, and the cell region isolation layer may include a first insulating film having a first side surface on an outer side surface of the outermost active pattern and extending in the second direction, and a second insulating film including a first portion on a second side surface of the first insulating film, the first side surface of the first insulating film being opposite the second side surface of the first insulating film, and a second portion extending in the first direction from a first end of the first portion at the second side surface of the first insulating film, and a lower surface of the second portion in a third direction may contact an upper surface of the bit line in the third direction, the third direction intersecting each of the first direction and the second direction.

According to some embodiments of the present disclosure, a semiconductor memory device may include a substrate having a cell region and a connection region at one side of the cell region, a bit line on the substrate and extending in a first direction across the cell region and the connection region, a plurality of word lines on the cell region on the bit line, each word line of the plurality of word lines being spaced apart from an adjacent word line in the first direction, the plurality of word lines include a first word line and a second word line each extending in a second direction intersecting the first direction, a plurality of active patterns on the cell region, the plurality of active patterns including a first active pattern on a first side surface of the first word line and a second active pattern on a second side surface of the second word line opposite to the first side surface of the second word line, and a cell region isolation layer on the bit line on the connection region. The cell region isolation layer may include a first insulating film and a second insulating film that are sequentially on an outer side surface of a third active pattern that is an outermost active pattern among the plurality of active patterns in the first direction that defines a boundary between the cell region and the connection region, and a lower surface of the second insulating film may contact an upper surface of the bit line in a third direction intersecting each of the first direction and the second direction.

According to some embodiments of the present disclosure, a semiconductor memory device may include a substrate having a cell region and a connection region at one side of the cell region, a bit line on the substrate and extending in a first direction across the cell region and the connection region, a plurality of word lines on the cell region on the bit line, each word line of the plurality of word lines being spaced apart from an adjacent word line in the first direction, the plurality of word lines including a first word line and a second word line each extending in a second direction intersecting the first direction, a plurality of active patterns on the cell region, the plurality of active patterns including a first active pattern on a first side surface of the first word line and a second active pattern on a second side surface of the second word line opposite the first side surface of the second word line, and a cell region isolation layer on the bit line on the connection region. The cell region isolation layer may include a first insulating film, a second insulating film, and a third insulating film that are sequentially on an outer side surface of a third active pattern that is an outermost active pattern among the plurality of active patterns, the outer side surface of the outermost active pattern in the first direction defining a boundary between the cell region and the connection region. The first insulating film and the second insulating film may be different materials, and the first insulating film and the third insulating film may be the same material. A lower surface of the first insulating film and a lower surface of the second insulating film may contact an upper surface of the bit line, and the second insulating film may include a portion between the third insulating film and the bit line.

According to some embodiments of the present disclosure, a method of manufacturing a semiconductor memory device may include preparing a preliminary substrate including a preliminary cell region and a preliminary connection region disposed at one side of the preliminary cell region, forming a cell isolation trench in the preliminary connection region, sequentially forming a first preliminary insulating film, a second preliminary insulating film, and a third preliminary insulating film on an inner wall of the cell isolation trench and on an upper surface of the preliminary substrate in the preliminary cell region, forming a plurality of word lines spaced apart from an adjacent word line in a first direction within the preliminary cell region, each word line of the plurality of word lines extending in a second direction intersecting the first direction, forming a plurality of active patterns, each active pattern of the plurality of active patterns disposed on one side of a corresponding word line of the plurality of word lines in the preliminary cell region, polishing the preliminary substrate in the preliminary cell region and the preliminary connection region down to a lower surface of the first preliminary insulating film, and polishing the first preliminary insulating film down to a lower surface of the second preliminary insulating film in the preliminary connection region so as to form a cell isolation insulating film including a first insulating film, a second insulating film, and a third insulating film that are sequentially disposed on an inner wall of the cell isolation trench.

According to some embodiments of the present disclosure, the method of manufacturing a semiconductor memory device may further include forming a bit line contacting a lower surface of the active pattern and a lower surface of the second insulating film and extending in the first direction.

According to some embodiments of the present disclosure, the method of manufacturing a semiconductor memory device may further include, after forming the active pattern, forming a landing pad connected to the active pattern, and forming a capacitor structure connected to the landing pad.

According to some embodiments of the present disclosure, forming the cell isolation insulating film may include forming a cell isolation insulating film including a first insulating film disposed on an inner wall of the cell isolation trench, a second insulating film including a first portion of the second insulating film disposed on one side surface of the first insulating film and a second portion of the second insulating film extending in a direction parallel to a surface of the preliminary substrate from an end of the first portion of the second insulating film, and a third insulating film disposed on the first portion of the second insulating film and the second portion of the second insulating film.

According to some embodiments of the present disclosure, forming the cell isolation insulating film may include forming the first insulating film and the second insulating film such that a first width in the first direction of the first insulating film, a second width in the first direction of the first portion of the second insulating film, and a third width in a third direction intersecting each of the first direction and the second direction of the second portion of the second insulating film, are the same as each other.

According to some embodiments of the present disclosure, forming the cell isolation insulating film may include forming the first insulating film and the second insulating film such that a first width in the first direction of the first insulating film is greater than both a second width in the first direction of the first portion of the second insulating film and a third width in the third direction, intersecting each of the first direction of the second insulating film and the second direction, of the second portion of the second insulating film.

According to some embodiments of the present disclosure, forming the cell isolation insulating film may include forming the first insulating film and the second insulating film such that a first width in the first direction of the first insulating film is smaller than both a second width in the first direction of the first portion of the second insulating film and a third width in the third direction, intersecting each of the first direction and the second direction, of the second portion of the second insulating film.

According to some embodiments of the present disclosure, the method of manufacturing a semiconductor memory device may further include forming a gate capping layer disposed between the plurality of word lines and the bit line, wherein a lower surface of the gate capping layer may be disposed coplanar with a lower surface of the second insulating film.

According to some embodiments of the present disclosure, a multi-insulating film of a cell region isolation layer in the connection region may function as a CMP stopper during a CMP process, thereby improving surface planarity and thickness uniformity. Through this, a semiconductor memory device having improved electrical characteristics and reliability may be provided.

### BRIEF DESCRIPTION OF THE DRAWINGS

FIG. 1 is a layout diagram illustrating a semiconductor memory device according to exemplary embodiments of the present disclosure.

FIG. 2 is a layout diagram illustrating a semiconductor memory device according to exemplary embodiments of the present disclosure.

FIG. 3 is an enlarged view of region Q of FIG. 2.

FIG. 4 is a cross-sectional view taken along line A-A of FIG. 3.

FIG. 5 is an enlarged view of region R1 of FIG. 4.

FIGS. 6 to 8 are enlarged views of region R2 of FIG. 4.

FIG. 9 is a diagram for describing a semiconductor memory device according to exemplary embodiments of the present disclosure.

FIGS. 10 and 11 are layout diagrams illustrating a semiconductor memory device according to exemplary embodiments of the present disclosure.

FIGS. 12 to 19 are intermediate process diagrams for describing a method of manufacturing a semiconductor memory device according to some embodiments of the present disclosure.

FIG. 20 is a flowchart for describing a method of manufacturing a semiconductor memory device according to some embodiments of the present disclosure.

### DETAILED DESCRIPTION

Hereinafter, various embodiments of the present disclosure are described with reference to the drawings. The same reference numerals throughout the specification may refer to the same components.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” or “substantially constant,” may be exactly the same, or constant, or may be the same or constant within acceptable variations that may occur, for example, due to manufacturing processes.

It will be understood that when an element is referred to as being "connected" to or “on” another element, it can be directly connected to or on the other element or intervening elements may be present. In contrast, when an element is referred to as “contacting” or “in contact with” another element (or using any form of the word “contact”), there are no intervening elements present at the point of contact. As used herein the terms “on”, “over”, or “covering” are intended to mean that an element is over another element. The elements may be touching or not. For example, there may be layers between layers that are “on” one another. An element “on” or “over” or “stacked” or “covering” another element need not cover an entire top surface of an element below to be considered “on” or “over” or “stacked” or “covering”. The terms are intended to encompass one element “on” or “over” or “stacked” or “covering” all, or any part of, an element below it.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Spatially relative terms, such as “lower,” “above,” “upper,” “inner,” “outer”, “outermost” and the like, may be used herein for ease of description to describe positional relationships, such as illustrated in the figures, for example. It will be understood that the spatially relative terms encompass different orientations of the device in addition to the orientation depicted in the figures.

In the drawings, a first direction D1 and a second direction D2 may indicate the same plane. For example, the first direction D1 and the second direction D2 may indicate directions parallel to a surface of a substrate 100. A third direction D3 may indicate a direction perpendicular to each of the first direction D1 and the second direction D2. For example, the third direction D3 may indicate a direction perpendicular to the surface of the substrate 100. The first direction D1 and the second direction D2 may intersect each other.

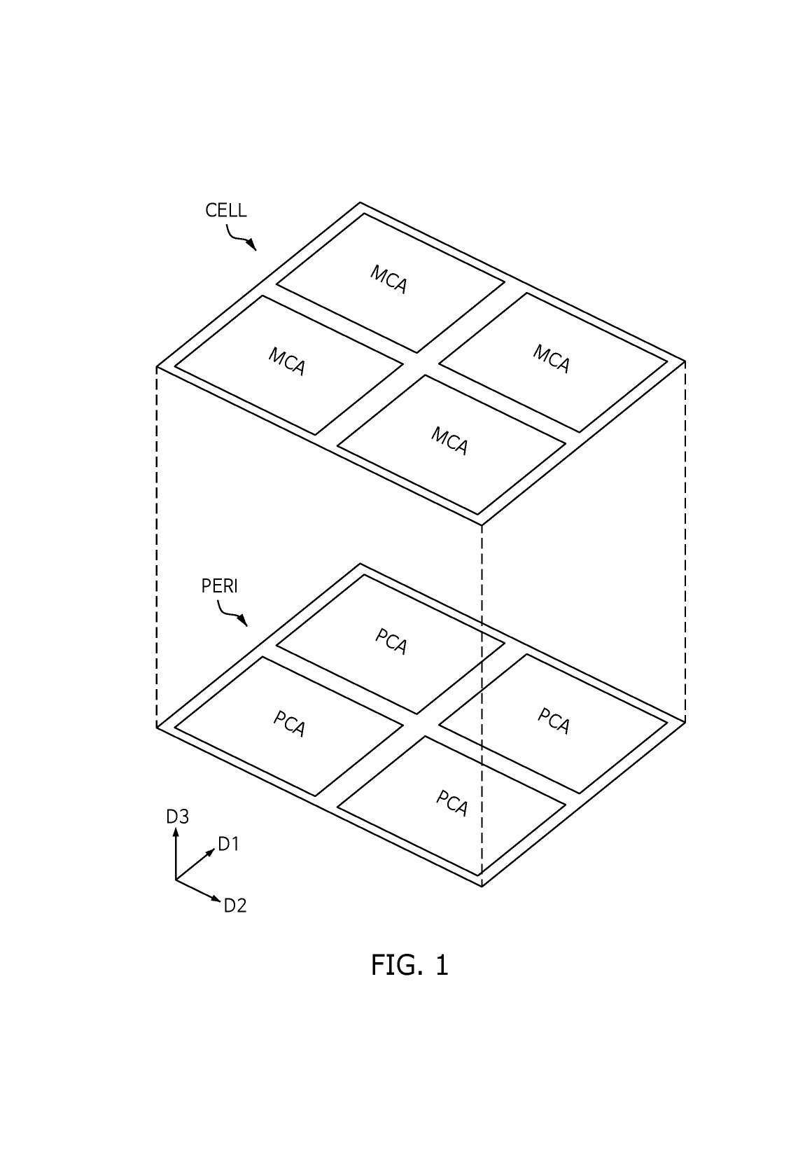

FIG. 1 is a layout diagram illustrating a semiconductor memory device according to exemplary embodiments of the present disclosure.

Referring to FIG. 1, the semiconductor memory device may include a cell structure CELL and a peripheral circuit structure PERI disposed in a vertical direction (for example, the third direction D3).

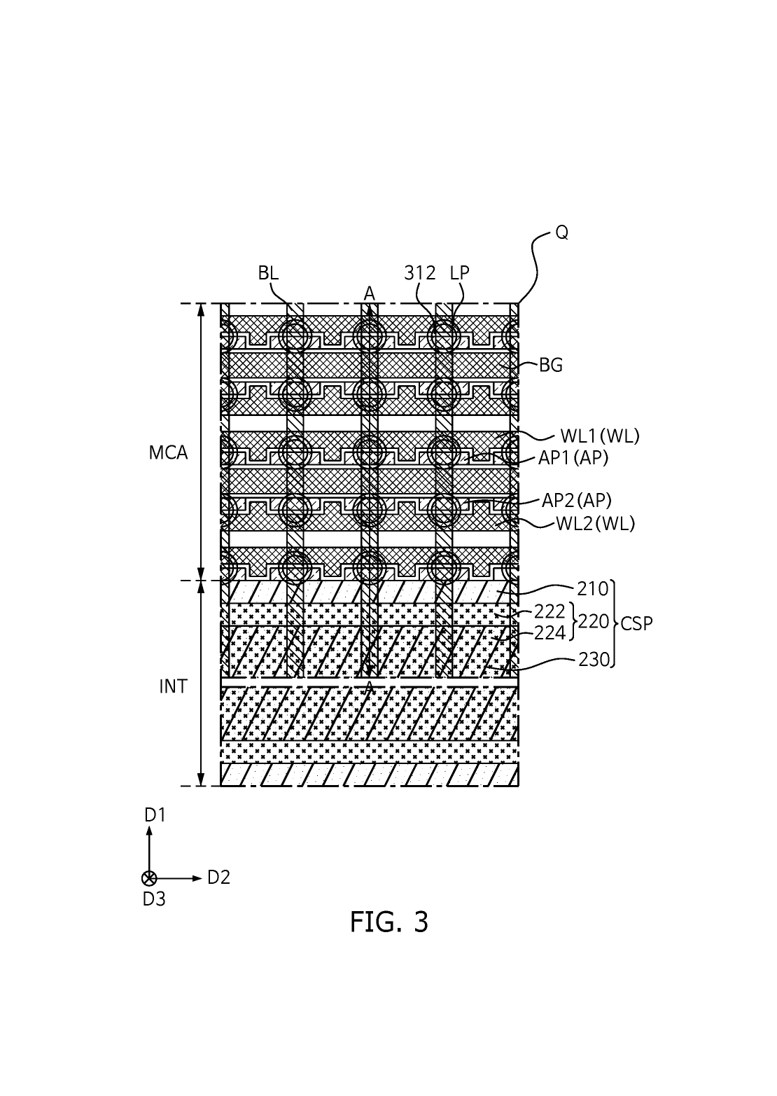

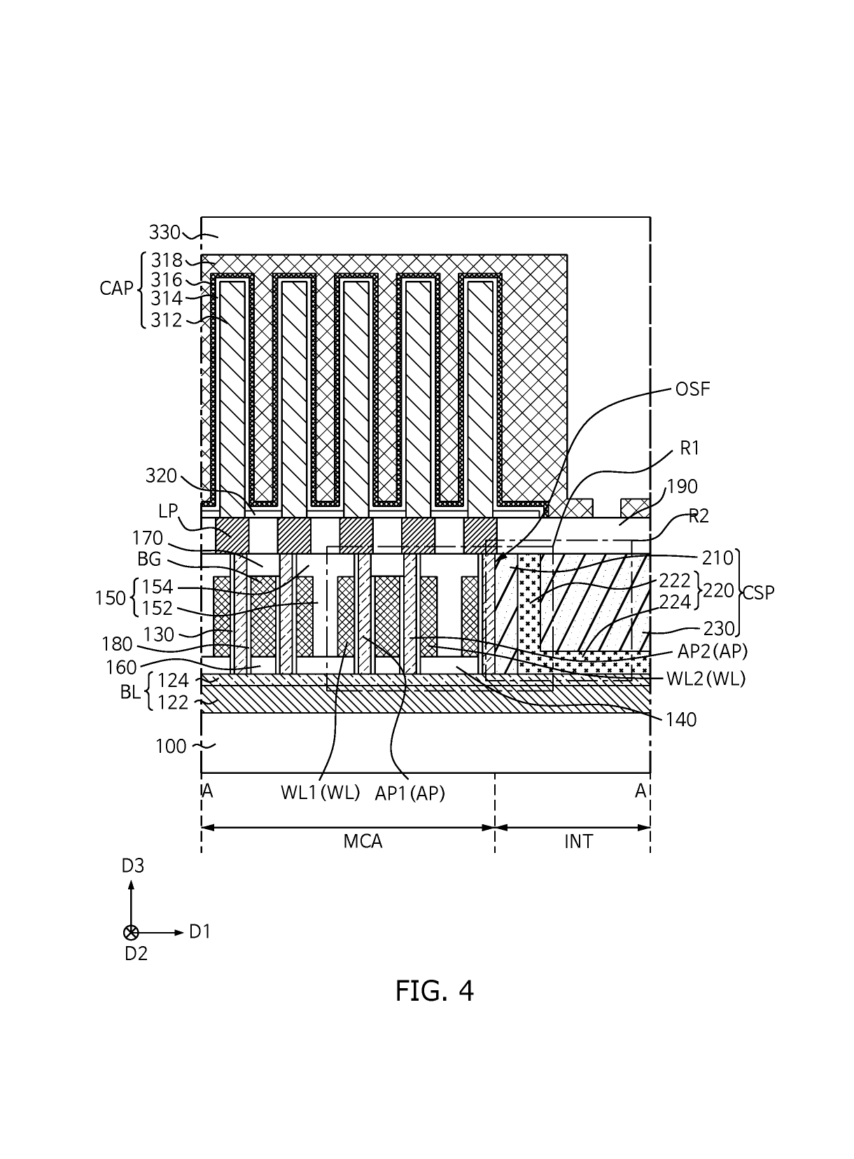

The cell structure CELL may include a plurality of cell regions MCA arranged in a matrix form. The cell region MCA may be a memory cell region of a DRAM. For example, the cell region MCA may include a memory cell transistor and a data storage element. In some embodiments, the memory cell transistor may be a vertical channel transistor (VCT). A gate of the memory cell transistor may be connected to a word line (for example, the word line WL of FIG. 3). In addition, a channel pattern of the memory cell transistor, for example, an active pattern (for example, the active pattern AP of FIG. 3), may be connected to a bit line (for example, the bit line BL of FIG. 3) and a data storage element. For example, the data storage element may be a capacitor structure (for example, the capacitor structure CAP of FIG. 4).

The peripheral circuit structure PERI may be a core region or peripheral circuit region of a DRAM. The peripheral circuit region PCA may include a peripheral circuit transistor for delivering a signal and/or power to cell transistors included in the cell region MCA. In exemplary embodiments, the peripheral circuit transistor may constitute various circuits such as a command decoder, control logic, address buffer, row decoder, column decoder, sense amplifier, or a data input/output circuit.

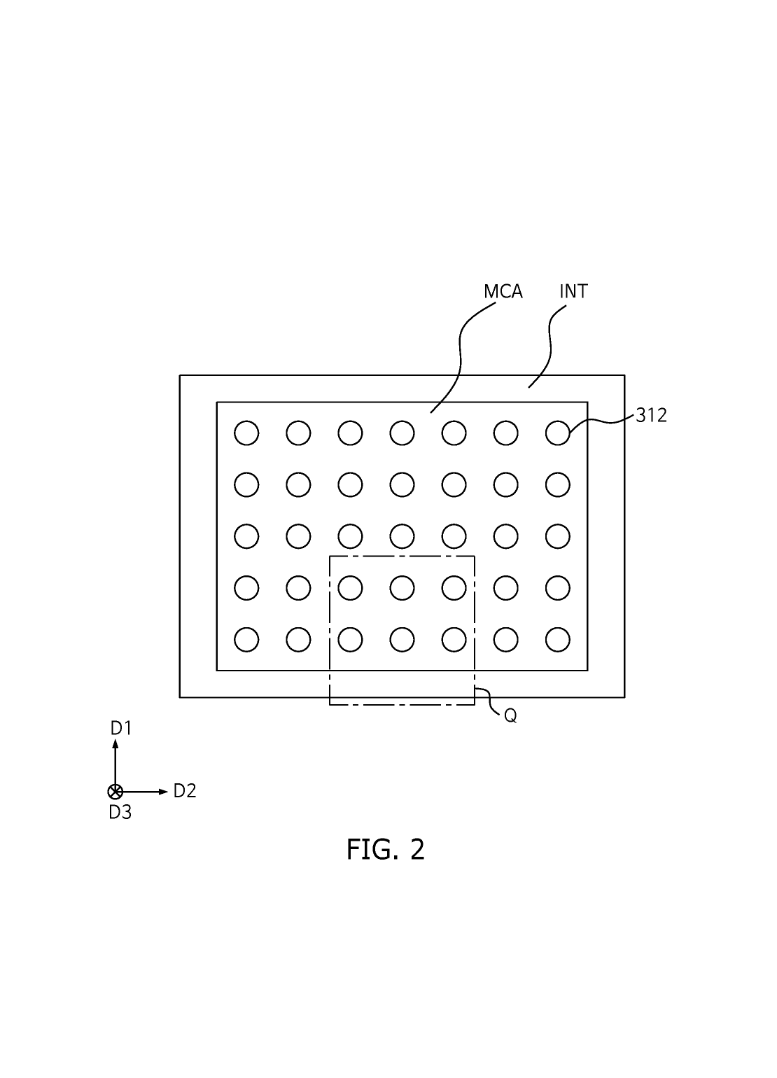

FIG. 2 is a layout diagram illustrating a semiconductor memory device according to exemplary embodiments of the present disclosure. Specifically, FIG. 2 is a schematic layout diagram of the cell region MCA of the semiconductor memory device shown in FIG. 1. In FIG. 2, configurations other than a first electrode 312 of a capacitor structure (for example, the capacitor structure CAP of FIG. 4) are omitted.

Referring to FIG. 2, a connection region INT may be disposed on a side of the cell region MCA. For example, the cell region MCA may be surrounded by the connection region INT. In some embodiments, the connection region INT may include an insulating pattern disposed to separate adjacent cell regions MCA from each other.

As shown in FIG. 2, a plurality of first electrodes 312 may be disposed on the cell region MCA. Although FIG. 2 illustrates a planar arrangement of the first electrodes 312 arranged in a matrix form, the arrangement form and number of the first electrodes 312 are exemplary, and the scope of the present disclosure is not limited thereto.

FIG. 3 is an enlarged view of region Q of FIG. 2. FIG. 4 is a cross-sectional view taken along line A-A of FIG. 3.

Referring to FIGS. 3 and 4, according to some embodiments of the present disclosure, the semiconductor memory device may include a substrate 100, a bit line BL, a word line WL, an active pattern AP, a gate capping layer 140, a gate isolation layer 150, a cell region isolation layer CSP, a landing pad LP, and a capacitor structure CAP.

The substrate 100 may be for example, a base substrate and may be formed of a crystalline semiconductor material. The substrate 100 may be, for example, a semiconductor substrate such as a silicon substrate, a germanium substrate, or a silicon-germanium substrate. In some embodiments, the cell substrate 100 may include or be polysilicon (poly Si).

In some embodiments, the substrate 100 may be an insulating material. For example, the substrate 100 may be an insulating substrate. In some embodiments, the substrate 100 may be composed of a wiring insulating layer including a wiring structure to connect a cell structure (for example, the cell structure CELL of FIG. 1) with a peripheral circuit structure (for example, the peripheral circuit structure PERI of FIG. 1).

The substrate 100 may include the cell region MCA and the connection region INT.

A memory cell array including a plurality of memory cells may be formed in the cell region MCA. For example, a bit line BL, a word line WL, and an active pattern AP described herein may be disposed in the cell region MCA.

The connection region INT may be disposed around one or more sides of the cell region MCA. For example, the connection region INT may surround the cell region MCA. A cell region isolation layer CSP may be disposed in the connection region INT.

In some embodiments, the substrate 100 may include a plurality of cell regions MCA, and the connection region INT may be disposed between cell regions MCA adjacent to each other. In an example, the cell regions MCA adjacent to each other may have symmetrical structures, but the scope of the present disclosure is not limited thereto.

A plurality of bit lines BL may be disposed on the substrate 100. Adjacent bit lines BL of the plurality of bit lines BL may be spaced apart from each other in a second direction D2. Each bit line BL may extend in a first direction D1, parallel to a surface of the substrate 100, across the cell region MCA and the connection region INT. In some embodiments, each bit line BL may be cut on the connection region INT. Adjacent bit lines of the plurality of bit lines BL may be arranged at equal intervals with respect to each other. The width of each bit line BL or the spacing between adjacent bit lines BL may be determined according to a design rule.

In some embodiments, each bit line BL may include or be a metal layer 122 and a polysilicon film 124 that are sequentially stacked in the third direction D3 on the substrate 100. The polysilicon film 124 may be polysilicon doped with an impurity, and the metal layer 122 may include or be a conductive material. The metal layer 122 may be a conductive metal nitride, for example, titanium nitride, or tantalum nitride, or a combination thereof. In addition, the metal layer 122 may be a metal silicide such as titanium silicide, cobalt silicide, or nickel silicide. However, the material included in the metal layer 122 is not limited thereto and may vary.

A plurality of word lines WL may be disposed above the bit lines BL. Specifically, the plurality of word lines WL may be spaced apart from the surface of the bit line BL in the third direction D3. In addition, adjacent word lines WL of the plurality of word lines WL may be spaced apart from adjacent word lines in the first direction D1. Each word line WL may extend in the second direction D2 intersecting the first direction D1.

The active pattern AP may be disposed on one side of a word line WL. In some embodiments, the plurality of word lines WL may include a first word line WL1 and a second word line WL2, which have active patterns AP disposed on different side surfaces of a word line. The first word line WL1 and the second word line WL2 may be alternately spaced apart along the first direction D1. For example, the first active pattern AP1 may be disposed on a first side surface of the first word line WL1. The second active pattern AP2 may be disposed on a second side surface, which is opposite the first side surface, of the second word line WL2.

Each active pattern AP may include or be a single-crystal semiconductor material. For example, the active pattern AP may include or be single-crystal silicon.

A gate insulating film 130 may be disposed between the word line WL and the active pattern AP. The gate insulating film 130 may extend in the third direction D3 between the word line WL and the active pattern AP. For example, the gate insulating film 130 may be disposed between the first word line WL1 and the first active pattern AP1 and may extend along a first side surface profile of the first word line WL1. In addition, the gate insulating film 130 may be disposed between the second word line WL2 and the second active pattern AP2 and may extend along a second side surface profile of the second word line WL2.

The gate insulating film 130 may include or be silicon oxide, silicon oxynitride, or a high-k dielectric material having a dielectric constant higher than that of silicon oxide, or a combination thereof. The high-k dielectric material may include or be a metal oxide or a metal oxynitride. For example, the high-k dielectric material that may be used for the gate insulating film 130 may include or be HfO₂, HfSiO, HfSiON, HfTaO, HfTiO, HfZrO, ZrO₂, or Al₂O₃, or a combination thereof, but is not limited thereto.

The gate capping layer 140 may be disposed between the word line WL and the bit line BL. For example, where an adjacent first word line WL1 and second word line WL2 face each other, the gate capping layer 140 may be disposed between lower surfaces of each of the first word line WL1 and the second word line WL2 and an upper surface of the bit line BL.

The gate capping layer 140 may include or be silicon oxide, silicon oxynitride, silicon nitride, or a low-k material having a dielectric constant lower than that of silicon oxide, or a combination thereof, but is not limited thereto.

The gate isolation layer 150 may be disposed between adjacent first word line WL1 and second word line WL2 facing each other. For example, the gate isolation layer 150 may be disposed on side surfaces of each of the first word line WL1 and the second word line WL2 and on upper surfaces of the first word line WL1 and the second word line WL2 to which they are connected.

Specifically, the gate isolation layer 150 may include a vertical part 152 extending in the third direction D3 along a second side surface of the first word line WL and a first side surface of the second word line WL, and a horizontal part 154 connected to an end of the vertical part 152 and disposed on upper surfaces of each of the first word line WL1 and the second word line WL2. In example embodiments, the second side surface of the first word line WL1 indicates a side surface opposite the first side surface of the first word line WL1 on which the first active pattern AP1 is disposed, and the first side surface of the second word line WL2 indicates a side surface opposite the second side surface of the second word line WL2 on which the second active pattern AP2 is disposed.

The gate isolation layer 150 may include or be, for example, silicon oxide, silicon oxynitride, silicon nitride, or a low-k material having a dielectric constant lower than that of silicon oxide, or a combination thereof, but is not limited thereto.

According to some embodiments, the semiconductor memory device may further include a back gate electrode BG, a back gate capping layer 160, a back gate isolation layer 170, and a back gate insulating film 180.

The back gate electrode BG may be disposed between a first active pattern AP1 and a second active pattern AP2 where the first active pattern AP1 and the second active pattern AP2 face each other. The back gate electrode BG may be spaced apart in the third direction D3 from the surface of the bit line BL. In addition, adjacent back gate electrodes BG of a plurality of back gate electrodes may be spaced apart from each other in the first direction D1. Each back gate electrode BG may extend in the same direction (for example, the second direction D2) as each word line WL. Although FIG. 4 shows that the height in the third direction D3 of the back gate electrode BG corresponds to that of the word line WL, the present disclosure is not limited thereto, and the height of the back gate electrode BG may differ from that of the word line WL.

The back gate electrode BG may include or be a conductive material. For example, the back gate electrode BG may include or be doped polysilicon, a conductive metal nitride, a conductive metal silicon nitride, a metal carbonitride, a conductive metal silicide, a conductive metal oxide, a two-dimensional material, or a metal, or a combination thereof.

In some embodiments, when the semiconductor memory device operates, a negative voltage may be applied to the back gate electrode BG, and a threshold voltage of a vertical channel transistor may be increased. For example, degradation of leakage current characteristics may be prevented which may occur as the vertical channel transistor miniaturizes and the threshold voltage reduces.

The back gate capping layer 160 may be disposed on a lower surface of the back gate electrode BG. For example, the back gate capping layer 160 may be disposed between the back gate electrode BG and the bit line BL along with the gate capping layer 140.

The back gate capping layer 160 may include or be an insulating material. For example, the back gate capping layer 160 may be silicon oxide, silicon nitride, or silicon oxynitride, or a combination thereof, but is not limited thereto.

The back gate isolation layer 170 may be disposed on an upper surface of the back gate electrode BG. For example, the back gate isolation layer 170 may be disposed between the back gate electrode BG and a contact interlayer insulating layer 190 described herein. In addition, a side surface of the back gate isolation layer 170 may contact a portion of side surfaces of each of the first active pattern AP1 and the second active pattern AP2 that are adjacent to each other. For example, a portion of side surfaces of each of the first active pattern AP1 and the second active pattern AP2 adjacent to each other may be in contact with the side surface of the back gate isolation layer 170.

The back gate isolation layer 170 may include or be an insulating material. For example, the back gate isolation layer 170 may include or be silicon oxide, silicon nitride, or silicon oxynitride, or a combination thereof, but is not limited thereto.

The back gate insulating film 180 may be disposed between the back gate electrode BG and the active pattern AP. The back gate insulating film 180 may extend in the third direction D3 between the back gate electrode BG and the active pattern AP. For example, the back gate insulating film 180 may extend in the third direction D3 along side surfaces in the first direction D1 of each of the back gate capping layer 160 and the back gate electrode BG.

The back gate insulating film 180 may include or be silicon oxide, silicon oxynitride, or a high-k dielectric material having a dielectric constant higher than that of silicon oxide, or a combination thereof. The high-k dielectric material may include or be a metal oxide or a metal oxynitride. For example, the high-k dielectric material that may be used for the gate insulating film 130 may include or be HfO₂, HfSiO, HfSiON, HfTaO, HfTiO, HfZrO, ZrO₂, or Al₂O₃, or a combination thereof, but is not limited thereto.

The cell region isolation layer CSP may be disposed on the bit line BL in the connection region INT.

The cell region isolation layer CSP may include a first insulating film 210, a second insulating film 220, and a third insulating film 230 that are sequentially disposed on an outer side surface OSF of an outermost active pattern AP among a plurality of active patterns AP. Here, the outermost active pattern AP may indicate an active pattern AP disposed at an outermost side of the cell region MCA in the first direction, and may indicate the active pattern AP among the plurality of active patterns AP that is closest to the connection region INT. In some examples, the outer side surface OSF of the outermost active pattern AP may be a criteria defining a boundary between the cell region MCA and the connection region INT.

The first insulating film 210 may have a first side surface disposed on the outer side surface OSF of the outermost active pattern AP. In addition, referring to FIG. 3, on one side (for example, a side adjacent to the connection region INT) of an outermost word line WL among the plurality of word lines WL, a plurality of outermost active patterns AP may be spaced apart from each other in the second direction D2. The first insulating film 210 may extend in the second direction D2 along one side surface (for example, a side surface adjacent to the connection region INT) of each active pattern of the plurality of outermost active patterns AP.

The second insulating film 220 may include a first portion (or a vertical extension part) 222 disposed on a second side surface opposite the first side surface (for example, an inner side surface) of the first insulating film 210, and a second portion (or a horizontal extension part) 224 extending in a horizontal direction (for example, the first direction D1 and the second direction D2) from a lower end of the first portion 222. For example, the second portion 224 may extend from a first end of the first portion 222 at the second side surface of the first insulating film 210. The second portion 224 may be disposed parallel to an upper surface of the substrate 100 or an upper surface of the bit line BL.

In some embodiments, a lower surface of the second portion 224 may contact an upper surface of the bit line BL. For example, the lower surface of the second portion 224 in the third direction D3 may include a portion contacting an upper surface of the bit line BL. In embodiments where the bit line BL has a configuration that is cut in the connection region INT, the lower surface of the second portion 224 may include a portion not contacting an upper surface of the bit line BL.

The third insulating film 230 may be disposed on the first portion 222 and the second portion 224 of the second insulating film 220. For example, the first insulating film 210 may be disposed on an outer side surface of the first portion 222. The third insulating film 230 may be disposed on an inner side surface of the first portion 222 and an upper surface of the second portion 224. The third insulating film 230 may overlap the second portion 224 in the third direction D3. The second insulating film 220 (for example, the first portion 222) may include a portion disposed between the first insulating film 210 and the third insulating film 230, and the second insulating film 220 (for example, the second portion 224) may include a portion disposed between the third insulating film 230 and the bit line BL.

The third insulating film 230 may extend in a horizontal direction (for example, the first direction D1 and the second direction D2). The third insulating film 230 may be disposed parallel to an upper surface of the substrate 100 or an upper surface of the bit line BL. The third insulating film 230 may be wrapped on multiple sides by the second insulating film 220. For example, both side surfaces in the first direction D1 of the third insulating film 230 and the lower surface of the third insulating film 230 may be surrounded by the second insulating film 220.

Referring to FIG. 3, the cell region isolation layer CSP may have a symmetrical configuration in the connection region INT. For example, the first insulating films 210 may be spaced apart from each other for example in the first direction D1 or the second direction D2. For example, each first insulating film 210 may be disposed in an edge region on a respective side of the connection region INT. The second insulating film 220 may be disposed inside the first insulating films 210. The second insulating film 220 may have a U-shape. For example, the second insulating film 220 may include a first portion 222 disposed inside each respective spaced first insulating film 210, and a second portion 224 connecting the lower end in the third direction D3 of the spaced first portions 222 to each other. The third insulating film 230 may be disposed on the inner side surfaces of the first portion 222 of the second insulating film 220 and the upper surface of the second portion 224. For example, the third insulating film 230 may fill a space defined by the inner side surfaces of the first portions 222 of the second insulating film 220 and the upper surface of the second portion 224 of the second insulating film 220.

In some embodiments, the first insulating film 210 and the second insulating film 220 may be different materials. The first insulating film 210 and the second insulating film 220 may be materials having different etch selectivities. For example, the first insulating film 210 may be silicon oxide, and the second insulating film 220 may be silicon nitride, but the scope of the present disclosure is not limited thereto. Additionally, the first insulating film 210 and the third insulating film 230 may be the same material. However, the scope of the present disclosure is not limited thereto.

The semiconductor memory device may further include a contact interlayer insulating layer 190. The contact interlayer insulating layer 190 may be disposed on the active pattern AP. In addition, the contact interlayer insulating layer 190 may contact the gate isolation layer 150, the back gate isolation layer 170, and the cell region isolation layer CSP. The contact interlayer insulating layer 190 may include or be an insulating material such as silicon oxide, or silicon nitride, or a combination thereof, but is not limited thereto.

The landing pad LP may be connected to the active pattern AP. For example, the landing pad LP may penetrate the contact interlayer insulating layer 190. The plurality of landing pads LP may be separated from each other by the contact interlayer insulating layer 190. The contact interlayer insulating layer 190 may be disposed between the plurality of landing pads LP.

The landing pad LP may include or be a conductive material. The conductive material may include or be, for example, doped polysilicon, a conductive metal nitride, a conductive metal silicon nitride, a metal carbonitride, a conductive metal silicide, a conductive metal oxide, a two-dimensional material, or a metal, or a combination thereof.

In some embodiments, although not illustrated, a buried contact may be disposed between the landing pad LP and the active pattern AP. The buried contact may be a conductive material. For example, the buried contact may be doped polysilicon, a conductive metal nitride, a conductive metal silicon nitride, a metal carbonitride, a conductive metal silicide, a conductive metal oxide, a two-dimensional material, or a metal, or a combination thereof, and may be composed of a single film and/or multiple films.

The capacitor structure CAP may include a first electrode 312, a dielectric film 314, a conductive film 316, and a second electrode 318.

The first electrode 312 may be disposed on the landing pad LP. The first electrode 312 may be electrically connected to the landing pad LP. A portion of the first electrode 312 may be disposed in an etch stop film 320. For example, the first electrode 312 may penetrate the etch stop film 320 to be connected to the landing pad LP.

In some embodiments, the first electrode 312 may have a pillar shape and may extend in the third direction D3. In addition, the first electrode 312 may include or be, for example, at least one of a conductive metal material (such as cobalt (Co), titanium (Ti), nickel (Ni), tungsten (W), or molybdenum (Mo)), a metal nitride (such as titanium nitride (TiN), titanium silicon nitride (TiSiN), titanium aluminum nitride (TiAlN), tantalum aluminum nitride (TaAlN), or tungsten nitride (WN)), a noble metal material (such as platinum (Pt), ruthenium (Ru), or iridium (Ir)), a conductive oxide film (such as PtO, RuO₂, IrO₂, SRO (SrRuO₃), BSRO ((Ba,Sr)RuO₃), CRO (CaRuO₃), LSCo), or a metal silicide film. However, the present disclosure is not limited thereto.

The dielectric film 314 may be disposed on the first electrode 312. The dielectric film 314 may extend along the profile of the side surface and the upper surface of the first electrode 312. In addition, the dielectric film 314 may be disposed on the etch stop film 320. Further, the dielectric film 314 may include or be, for example, a high-k material containing silicon oxide, silicon nitride, silicon oxynitride, and a metal. Although the dielectric film 314 is illustrated as a single film for convenience of explanation, it is not limited thereto. According to example embodiments, the dielectric film 314 may be multiple films.

The conductive film 316 may be disposed on the dielectric film 314. The conductive film 316 may extend along the profile of the dielectric film 314. The conductive film 316 may contact the dielectric film 314. The conductive film 316 may include or be, for example, at least one of a doped semiconductor material, a conductive metal nitride (such as titanium nitride, tantalum nitride, niobium nitride, or tungsten nitride), a metal (such as ruthenium, iridium, titanium, or tantalum), or a conductive metal oxide (such as iridium oxide or niobium oxide), but is not limited thereto.

The second electrode 318 may be disposed on the conductive film 316. For example, the second electrode 318 may fill empty spaces among the plurality of first electrodes 312. The second electrode 318 may fill spaces among the plurality of first electrodes 312 remaining after the dielectric film 314 and the conductive film 316 are formed. The second electrode 318 may be electrically connected to the conductive film 316. The second electrode 318 may include or be, for example, at least one of an elemental semiconductor film or a compound semiconductor film. The second electrode 318 may include a doped n-type or p-type impurity.

The semiconductor memory device may further include an upper interlayer insulating layer 330. The upper interlayer insulating layer 330 may be disposed on the cell region MCA and the connection region INT of the substrate 100. For example, the upper interlayer insulating layer 330 may contact the second electrode 318 in the cell region MCA. In addition, the upper interlayer insulating layer 330 may contact the contact interlayer insulating layer 190 disposed on the cell region isolation layer CSP in the connection region INT.

The upper interlayer insulating layer 330 may include or be an insulating material such as silicon oxide, or silicon nitride, or a combination thereof, but is not limited thereto.

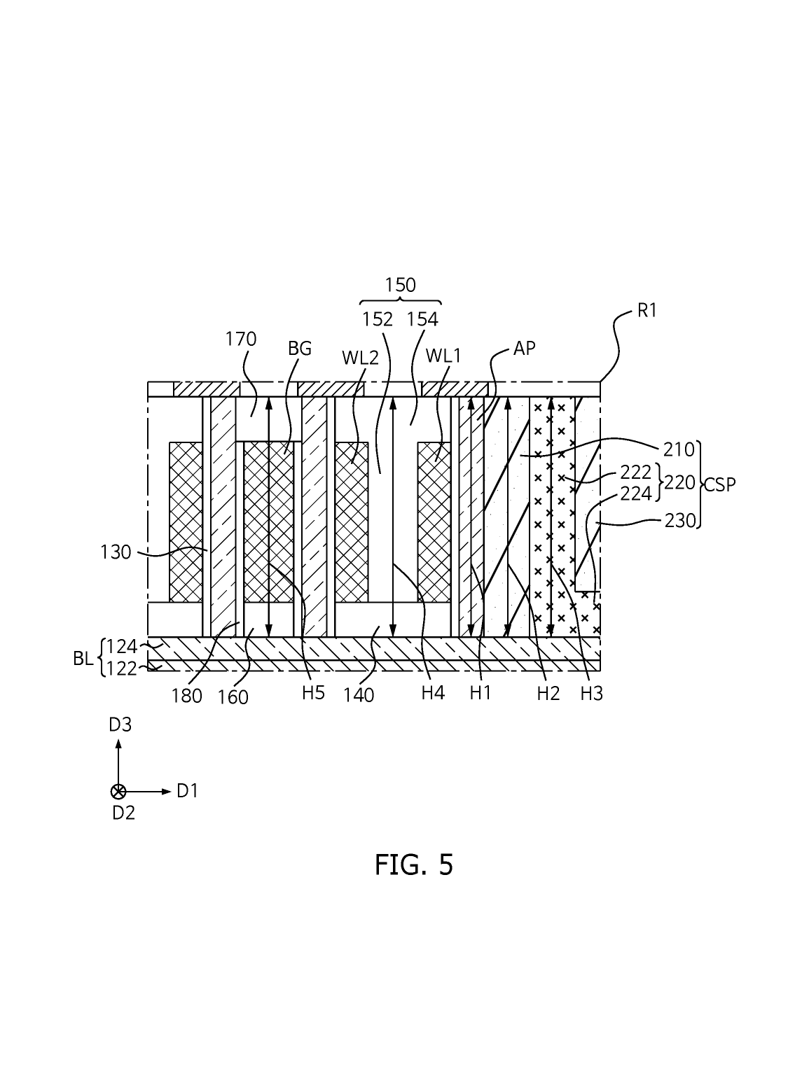

FIG. 5 is a diagram for describing a semiconductor memory device according to exemplary embodiments of the present disclosure. Specifically, FIG. 5 is an enlarged view of region R1 of FIG. 4. Hereinafter, for convenience of explanation, a description will focus on configurations different from those described in FIGS. 1 to 4. Like elements are as described herein with respect to other embodiments.

In some embodiments, a lower surface of the active pattern AP may be disposed on a coplanar surface with a lower surface of the second insulating film 220. For example, the lower surface of the active pattern AP and the lower surface of the second insulating film 220 may be aligned along the first direction D1. The lower surface of the active pattern AP and the lower surface of the second insulating film 220 may contact an upper surface of the bit line BL.

In some embodiments, a lower surface of the gate capping layer 140 may be coplanar with a lower surface of the second insulating film 220. For example, the lower surface of the gate capping layer 140 and the lower surface of the second insulating film 220 may be aligned along the first direction D1. The lower surface of the gate capping layer 140 and the lower surface of the second insulating film 220 may contact an upper surface of the bit line BL. Further, the gate capping layer 140 may overlap the second insulating film 220, for example, the second portion 224 of the second insulating film 220, in the first direction D1.

In some embodiments, a lower surface of the back gate capping layer 160 may be coplanar with a lower surface of the second insulating film 220. For example, the lower surface of the back gate capping layer 160 and the lower surface of the second insulating film 220 may be aligned along the first direction D1. The lower surface of the back gate capping layer 160 and the lower surface of the second insulating film 220 may contact an upper surface of the bit line BL. Further, the back gate capping layer 160 may overlap the second insulating film 220, for example, the second portion 224 of the second insulating film 220, in the first direction D1.

In some embodiments, a first distance H1 from an upper surface to a lower surface of the active pattern AP may be the same as a second distance H2 from an upper surface to a lower surface of the first insulating film 210. For example, a vertical level of the upper surface of the active pattern AP may correspond to a vertical level of the upper surface of the first insulating film 210, and a vertical level of the lower surface of the active pattern AP may correspond to a vertical level of the lower surface of the first insulating film 210.

In the present disclosure, the term “vertical level” may refer to a vertical level in the third direction D3. The “vertical level” may refer to a distance in the third direction D3 from a reference level to a surface of a specific configuration. The reference level may be a vertical level corresponding to an upper surface or a lower surface of an arbitrary component (for example, the substrate 100 or the bit line BL) having a planar surface.

In some embodiments, a first distance H1 from an upper surface to a lower surface of the active pattern AP may be the same as a third distance H3 from an upper surface to a lower surface of the first portion 222 of the second insulating film 220. For example, a vertical level of the upper surface of the active pattern AP may correspond to a vertical level of the upper surface of the first portion 222, and a vertical level of the lower surface of the active pattern AP may correspond to a vertical level of the lower surface of the first portion 222.

In some embodiments, a fourth distance H4 from an upper surface of the horizontal part 154 of the gate isolation layer 150 to a lower surface of the gate capping layer 140 may be the same as the second distance H2 from an upper surface to a lower surface of the first insulating film 210. For example, a vertical level of the upper surface of the horizontal part 154 of the gate isolation layer 150 may correspond to a vertical level of the upper surface of the first insulating film 210, and a vertical level of the lower surface of the gate capping layer 140 may correspond to a vertical level of the lower surface of the first insulating film 210.

In some embodiments, a fourth distance H4 from an upper surface of the horizontal part 154 of the gate isolation layer 150 to a lower surface of the gate capping layer 140 may be the same as a third distance H3 from an upper surface to a lower surface of the first portion 222 of the second insulating film 220. For example, a vertical level of the upper surface of the horizontal part 154 of the gate isolation layer 150 may correspond to a vertical level of the upper surface of the first portion 222, and a vertical level of the lower surface of the gate capping layer 140 may correspond to a vertical level of the lower surface of the first portion 222.

In some embodiments, a fifth distance H5 from an upper surface of the back gate isolation layer 170 to a lower surface of the back gate capping layer 160 may be the same as the second distance H2 from an upper surface to a lower surface of the first insulating film 210. For example, a vertical level of the upper surface of the back gate isolation layer 170 may correspond to a vertical level of the upper surface of the first insulating film 210, and a vertical level of the lower surface of the back gate capping layer 160 may correspond to a vertical level of the lower surface of the first insulating film 210.

In some embodiments, a fifth distance H5 from an upper surface of the back gate isolation layer 170 to a lower surface of the back gate capping layer 160 may be the same as a third distance H3 from an upper surface to a lower surface of the first portion 222 of the second insulating film 220. For example, a vertical level of the upper surface of the back gate isolation layer 170 may correspond to a vertical level of the upper surface of the first portion 222, and a vertical level of the lower surface of the back gate capping layer 160 may correspond to a vertical level of the lower surface of the first portion 222.

In some embodiments, the first insulating film 210 and the second insulating film 220 of the cell region isolation layer CSP may function as an etch stop layer or a polishing stop layer. The embodiments described with reference to FIG. 5 may be based on the fact that the first insulating film 210 and the second insulating film 220 serve as a CMP stopper in a Chemical Mechanical Polishing (CMP) process. Through this, surface planarity generated during the CMP process may be improved, and thickness uniformity may be enhanced, thereby providing a semiconductor memory device with improved electrical characteristics and/or reliability.

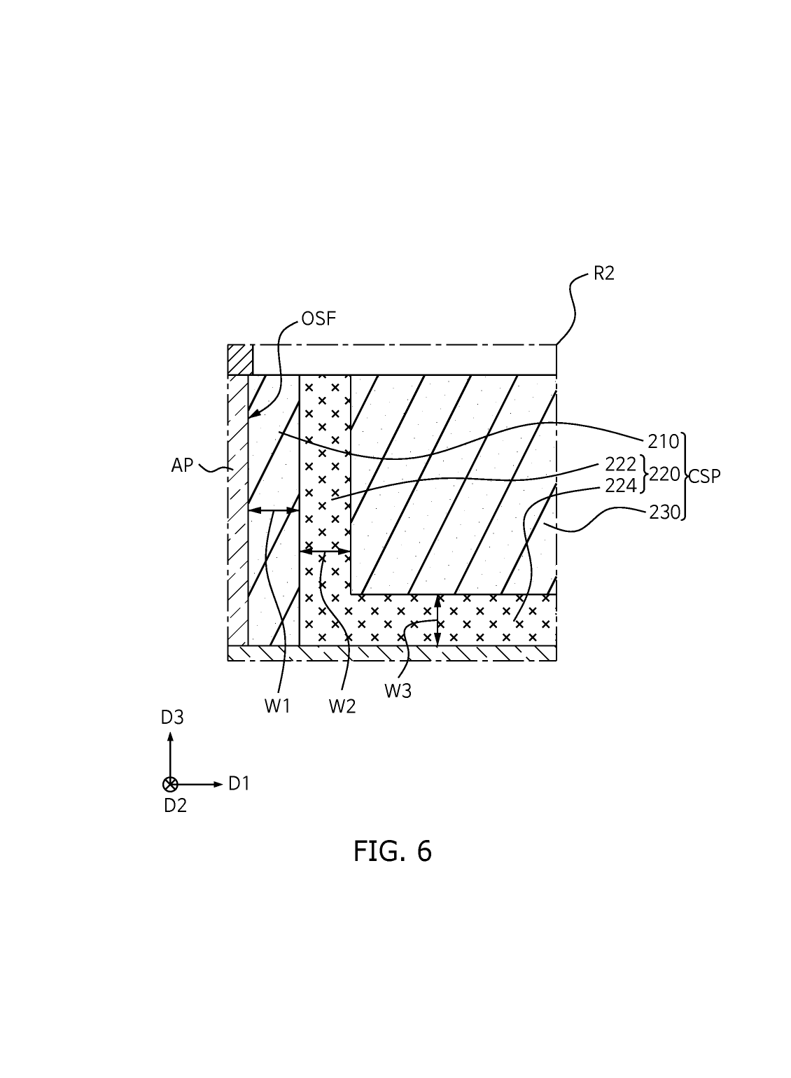

FIGS. 6 to 8 are diagrams for describing a semiconductor memory device according to exemplary embodiments of the present disclosure. Specifically, FIGS. 6 to 8 are enlarged views of region R2 of FIG. 4. Hereinafter, for convenience of explanation, a description will focus on configurations different from those described in FIGS. 1 to 5.

Referring to FIG. 6, a first width W1 of the first insulating film 210 in the first direction D1, a second width W2 of the first portion 222 of the second insulating film 220 in the first direction D1, and a third width W3 of the second portion 224 of the second insulating film 220 in the third direction D3, intersecting each of the first direction D1 and the second direction D2, may be the same as each other.

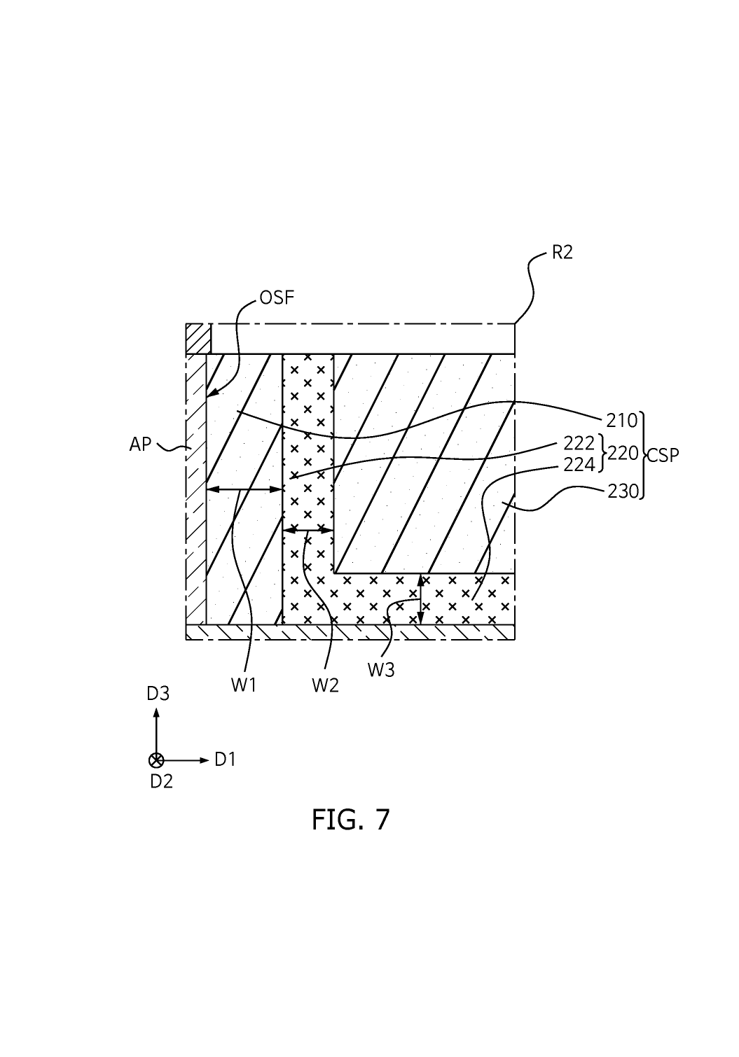

Referring to FIG. 7, the first width W1 of the first insulating film 210 in the first direction D1 may be greater than the second width W2 of the first portion 222 in the first direction D1 and the third width W3 of the second portion 224 in the third direction D3. For example, the second width W2 in the first direction D1 of the first portion 222 and the third width W3 in the third direction D3 of the second portion 224 may be smaller than the first width W1 of the first insulating film 210 in the first direction D1. In embodiments, the second width W2 and the third width W3 may be the same as each other, but the present disclosure is not limited thereto. The second width W2 and the third width W3 may differ from each other.

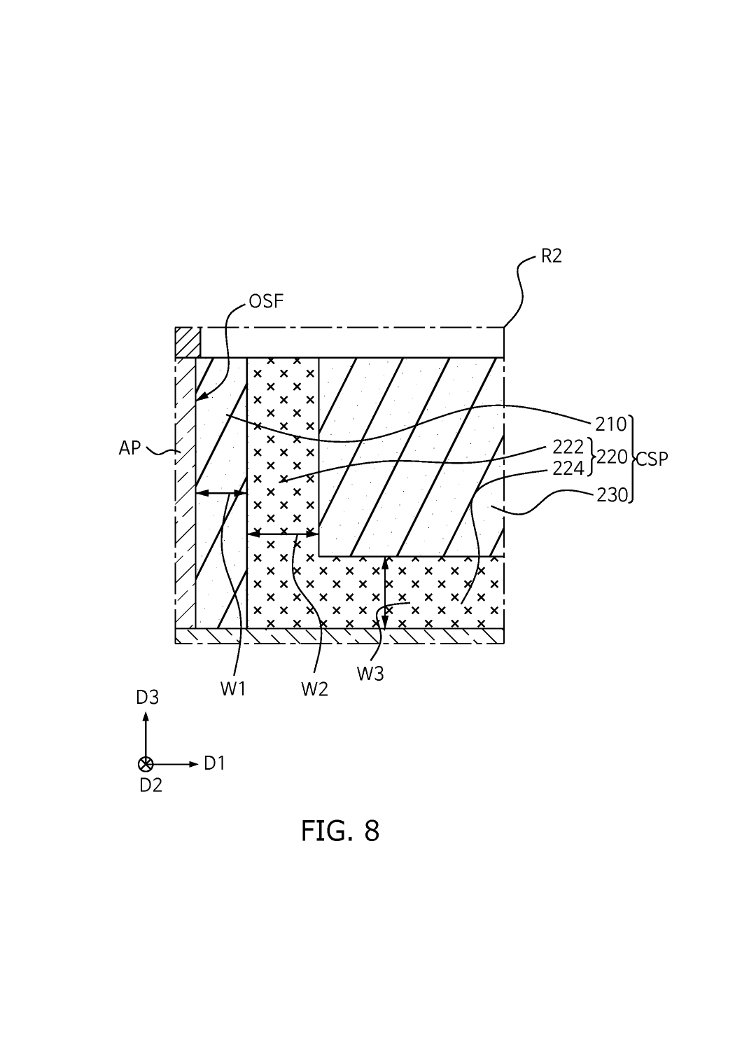

Referring to FIG. 8, the first width W1 of the first insulating film 210 in the first direction D1 may be smaller than the second width W2 of the first portion 222 in the first direction D1 and the third width W3 of the second portion 224 in the third direction D3. For example, the second width W2 of the first portion 222 in the first direction D1 and the third width W3 of the second portion 224 in the third direction D3 may be greater than the first width W1 of the first insulating film 210 in the first direction D1. In embodiments, the second width W2 and the third width W3 may be the same as each other, but the present disclosure is not limited thereto. The second width W2 and the third width W3 may differ from each other.

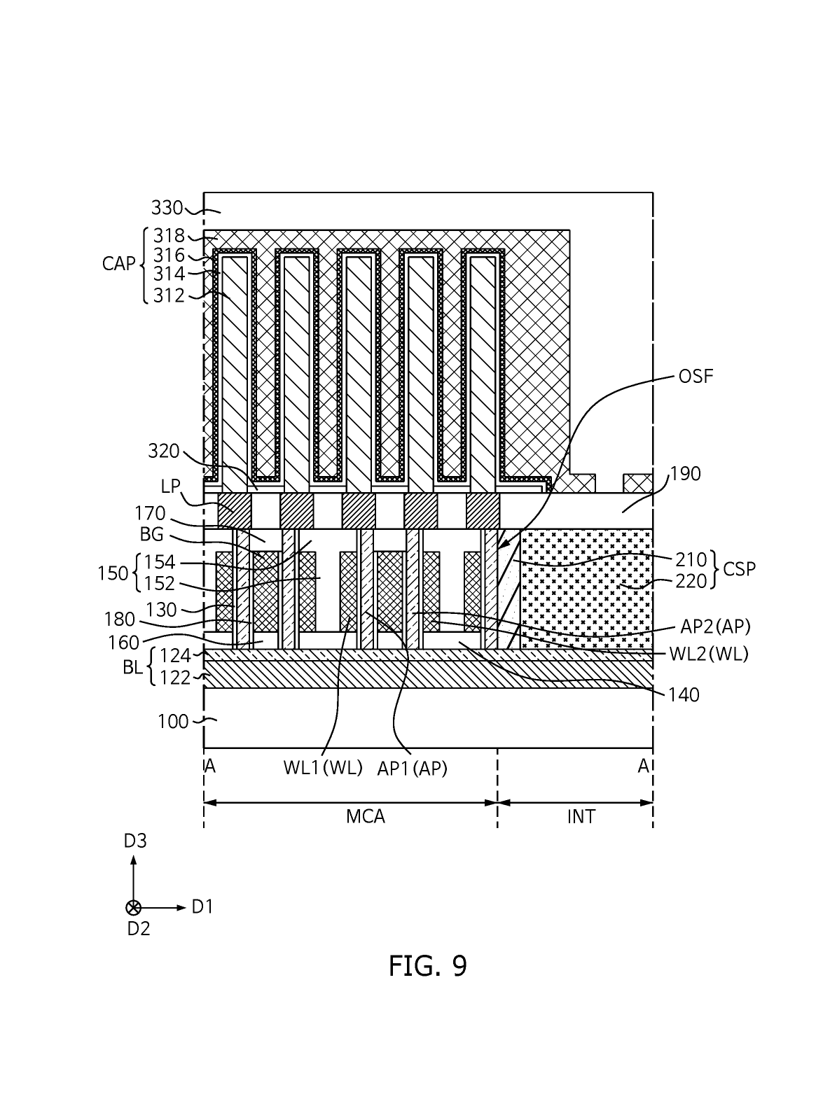

FIG. 9 is a diagram for describing a semiconductor memory device according to exemplary embodiments of the present disclosure. FIG. 9 may correspond to a cross-sectional view taken along line A-A of FIG. 2. A semiconductor memory device in FIG. 9 may be substantially the same as the semiconductor memory device described with reference to FIGS. 1 to 8, except for a shape of the cell region isolation layer CSP. Hereinafter, for convenience of explanation, a description will focus on configurations different from those described in FIGS. 1 to 8.

In some embodiments, the cell region isolation layer CSP may include a first insulating film 210 and a second insulating film 220 that are sequentially disposed on an outer side surface OSF of an outermost active pattern AP among a plurality of active patterns AP. The first insulating film 210 may be disposed adjacent to the active pattern AP on the cell region MCA. In addition, the second insulating film 220 may be disposed on one side surface of the first insulating film 210. In some embodiments, a lower surface of the second insulating film 220 may contact an upper surface of the bit line BL.

In some embodiments, a distance from an upper surface to a lower surface of the first insulating film 210 may be the same as a distance from an upper surface to a lower surface of the second insulating film 220. For example, a vertical level of the upper surface of the first insulating film 210 may correspond to a vertical level of the upper surface of the second insulating film 220, and a vertical level of the lower surface of the first insulating film 210 may correspond to a vertical level of the lower surface of the second insulating film 220.

In some embodiments, a height of the second insulating film 220, for example, the distance from the upper surface to the lower surface of the second insulating film 220, may remain substantially constant within the connection region INT.

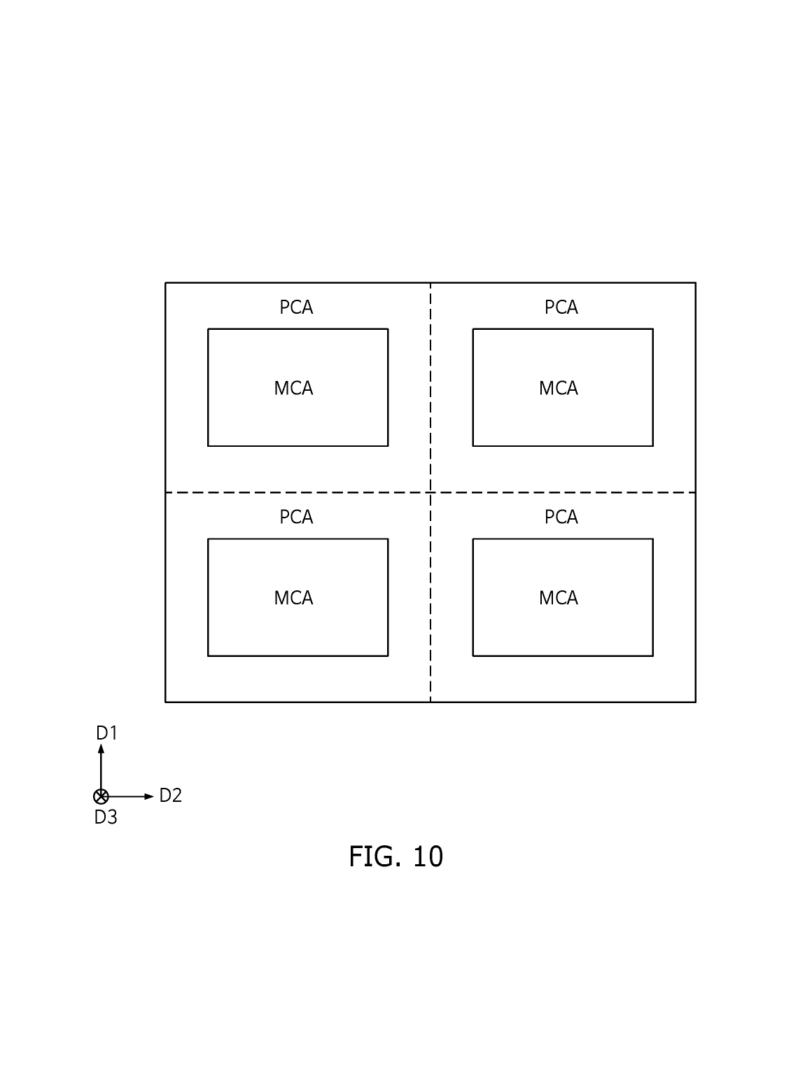

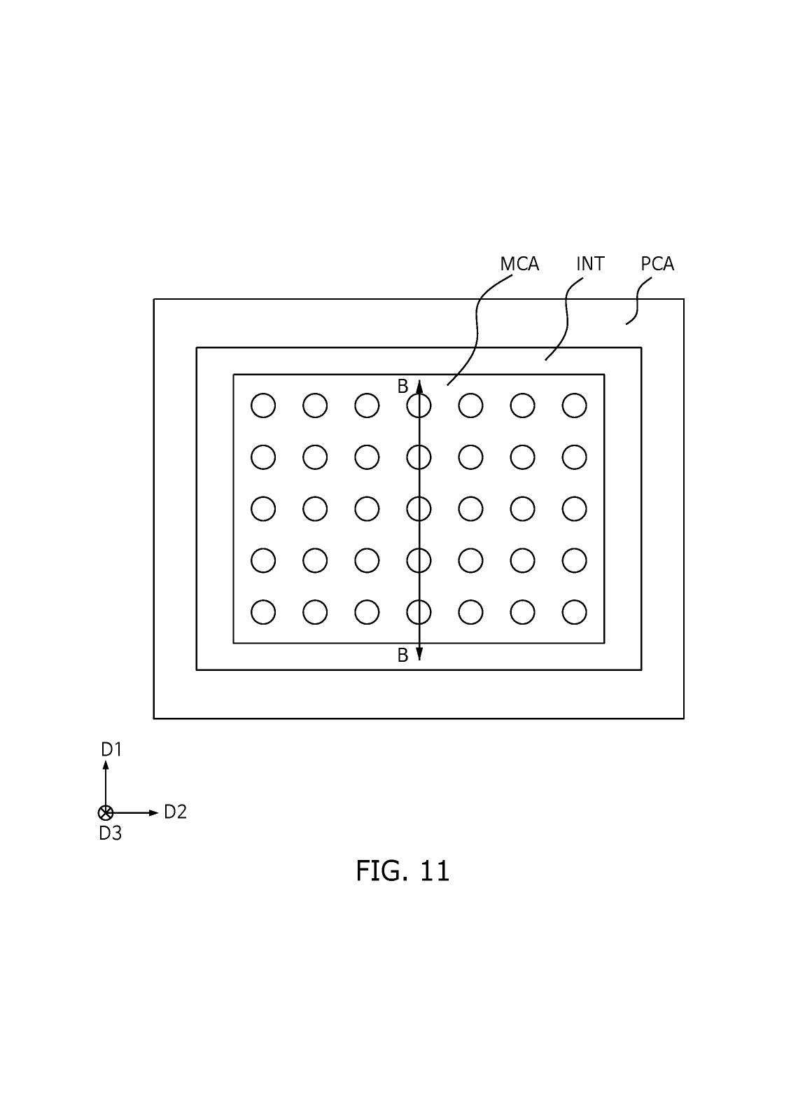

FIGS. 10 and 11 are layout diagrams illustrating a semiconductor memory device according to exemplary embodiments of the present disclosure. A semiconductor memory device of FIGS. 10 and 11 may be substantially the same as the semiconductor memory device described with reference to FIGS. 1 to 9, except for the arrangement shape of the cell region MCA and the peripheral circuit region PCA. Hereinafter, for convenience of explanation, a description will focus on configurations different from those described in FIGS. 1 to 9. The semiconductor memory device described with reference to FIGS. 1 to 9 may correspond to a cross-sectional view taken along line B-B of FIG. 11.

Referring to FIGS. 10 and 11, the semiconductor memory device may include a cell region MCA and a peripheral circuit region PCA disposed in a plane (for example, the first direction D1 and the second direction D2).

The peripheral circuit region PCA may be disposed around the cell region MCA. For example, the peripheral circuit region PCA may surround the cell region MCA. In embodiments, the connection region INT may be disposed between the cell region MCA and the peripheral circuit region PCA that surrounds the cell region MCA. In some embodiments, the connection region INT may include an insulating pattern disposed to separate the adjacent cell region MCA and the peripheral circuit region PCA from each other.

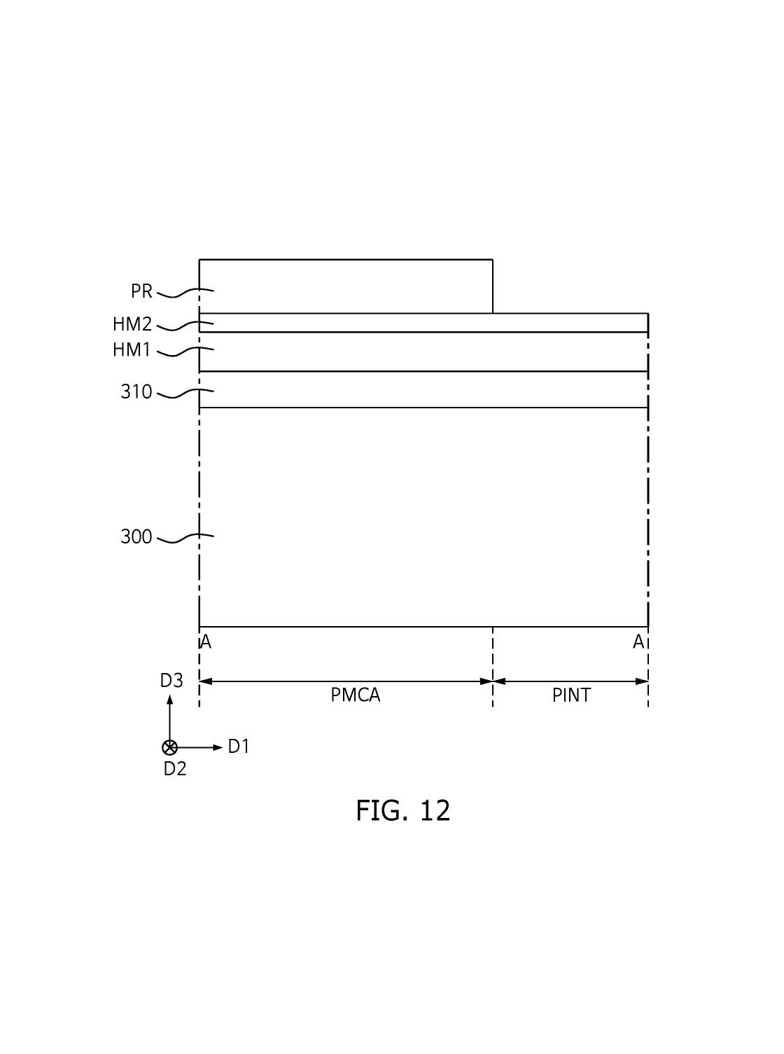

FIGS. 12 to 19 are intermediate process diagrams for describing a method of manufacturing a semiconductor memory device according to some embodiments of the present disclosure. FIGS. 12 to 19 may correspond to cross-sectional views taken along A-A of FIG. 2 or B-B of FIG. 11. Hereinafter, for convenience of explanation, an example will be described based on a cross-sectional view taken along A-A of FIG. 2.

Referring to FIG. 12, a preliminary substrate 300 including a preliminary cell region PMCA and a preliminary connection region PINT disposed at one side of the preliminary cell region PMCA may be provided. On the preliminary substrate 300, a preliminary insulating layer 310, a first mask layer HM1, a second mask layer HM2, and a photoresist layer PR may be formed.

The preliminary insulating layer 310 may be for example, silicon nitride. The first mask layer HM1 may include an SOH (Spin on hardmask) pattern. The second mask layer HM2 may be for example, silicon nitride. However, the scope of the present disclosure is not limited thereto. The materials of the preliminary insulating layer 310, the first mask layer HM1, and the second mask layer HM2 are not limited thereto and may vary.

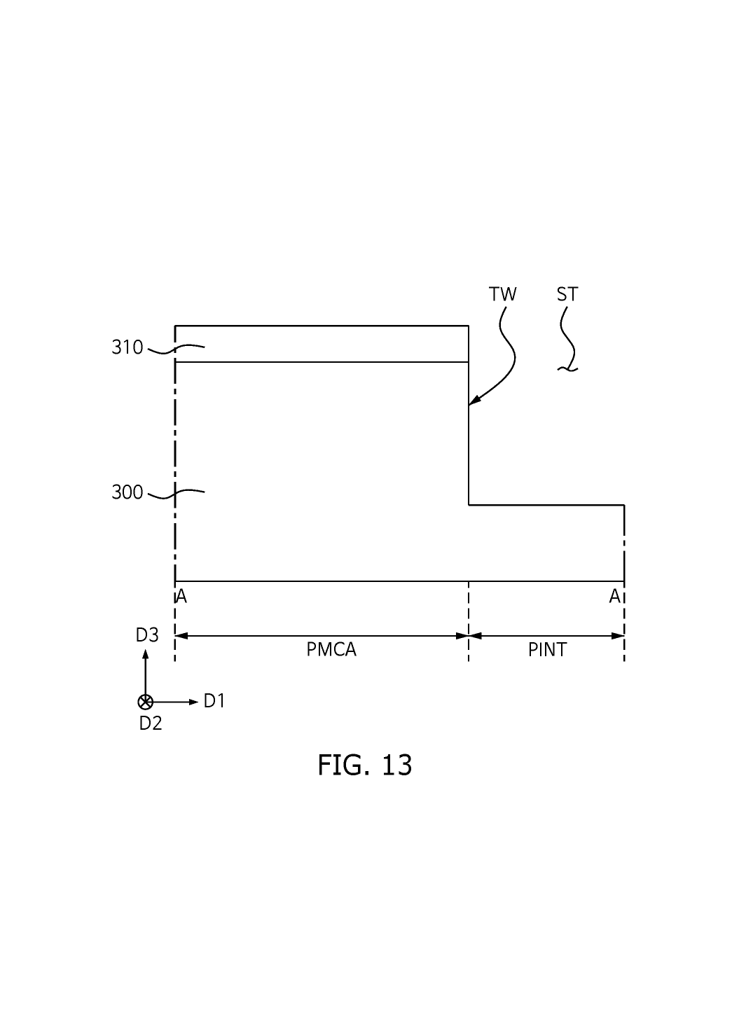

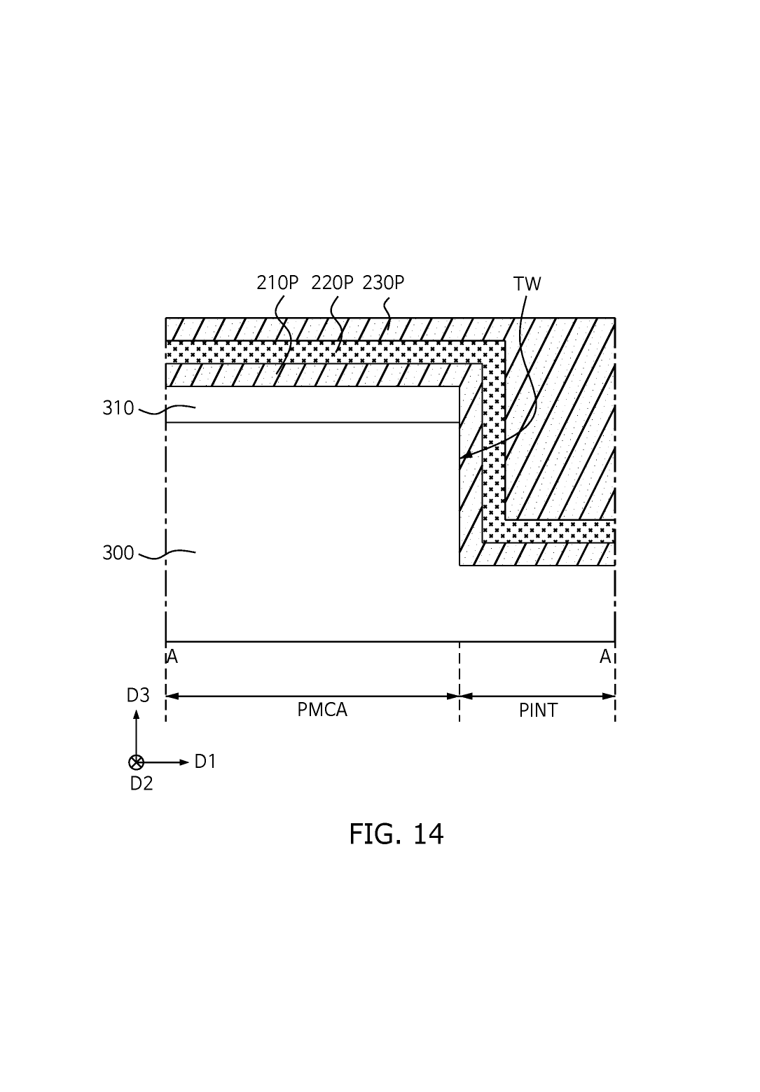

Referring to FIGS. 13 and 14, by patterning the preliminary connection region PINT, a cell isolation trench ST may be formed in the preliminary connection region PINT. Subsequently, a first preliminary insulating film 210P, a second preliminary insulating film 220P, and a third preliminary insulating film 230P may be sequentially formed on an inner wall TW of the cell isolation trench ST and on an upper surface of the preliminary insulating layer 310 of the preliminary cell region PMCA. In embodiments, the third preliminary insulating film 230P may be formed so that the height of an upper surface thereof may remain constant in the preliminary cell region PMCA and the preliminary cell region PMCA.

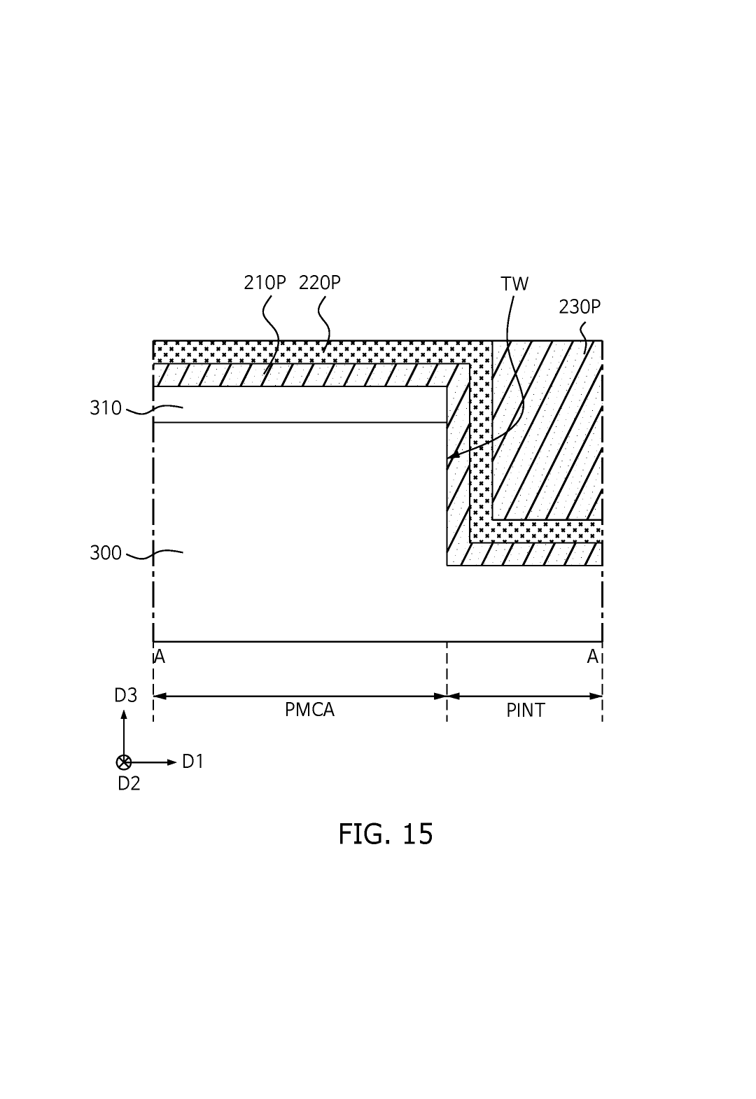

Referring to FIG. 15, the third preliminary insulating film 230P may be polished. For example, the third preliminary insulating film 230P may be polished down to an upper surface of the second preliminary insulating film 220P. Accordingly, in the preliminary cell region PMCA, the second preliminary insulating film 220P may be exposed, and an upper surface of the third preliminary insulating film 230P in the preliminary connection region PINT may be coplanar with the upper surface of the second preliminary insulating film 220P in the preliminary cell region PMCA. In some embodiments, the third preliminary insulating film 230P may be polished by a CMP process.

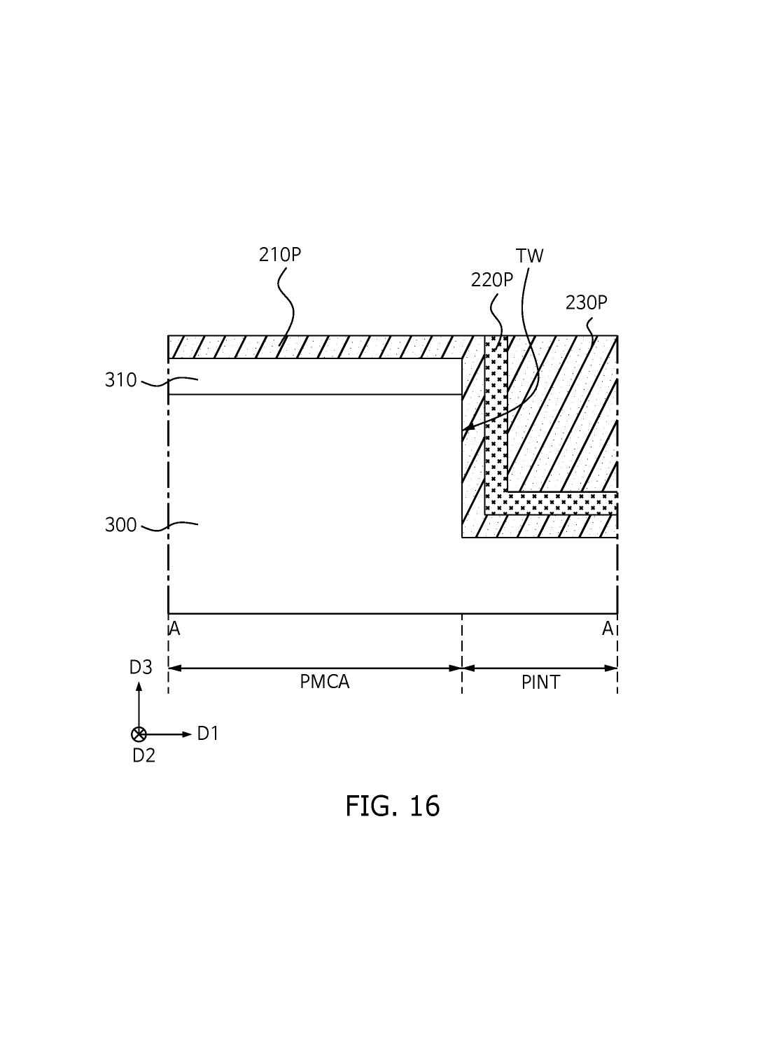

Referring to FIG. 16, the second preliminary insulating film 220P may be polished. For example, the second preliminary insulating film 220P may be polished down to an upper surface of the first preliminary insulating film 210P. Accordingly, in the preliminary cell region PMCA, the first preliminary insulating film 210P may be exposed, and upper surfaces of each of the second preliminary insulating film 220P and the third preliminary insulating film 230P in the preliminary connection region PINT may be coplanar with the upper surface of the first preliminary insulating film 210P in the preliminary cell region PMCA. In some embodiments, the second preliminary insulating film 220P may be polished by a CMP process.

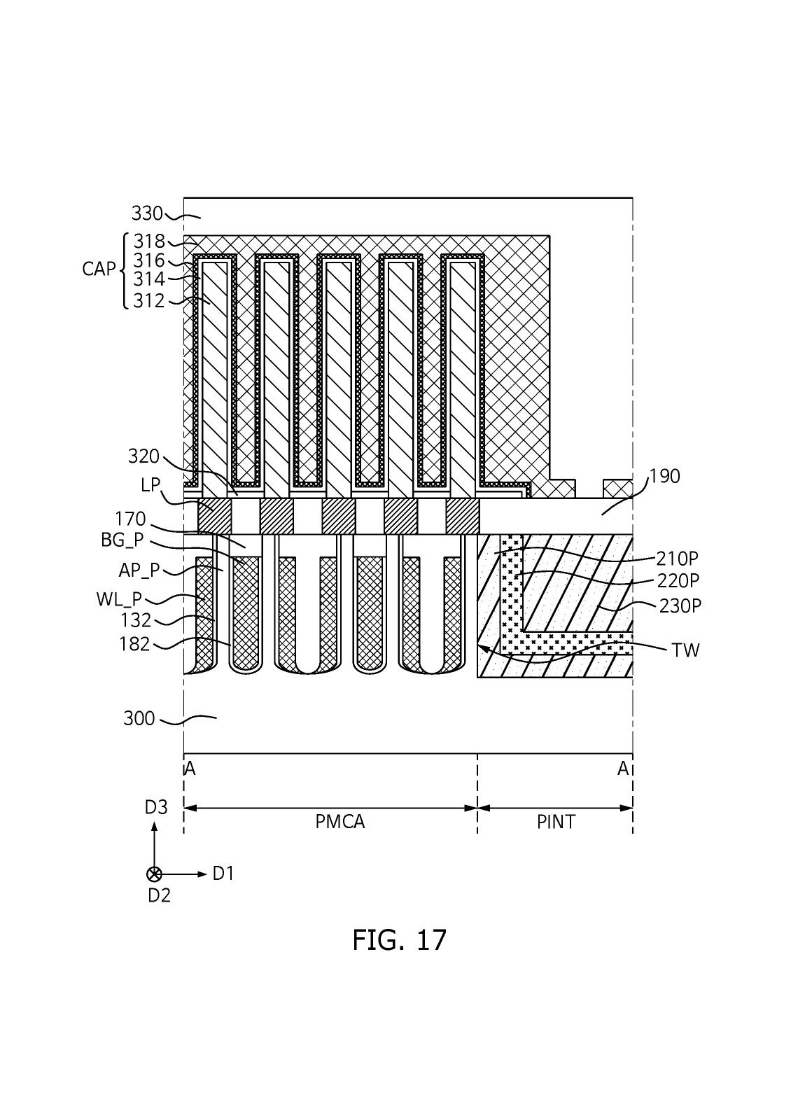

Referring to FIG. 17, a plurality of word lines may be formed in the preliminary substrate 300. For example, after patterning the preliminary substrate 300, a preliminary gate insulating film 132 may be formed in the patterned recess, and then preliminary word lines WL_P may be formed spaced apart from adjacent preliminary word lines WL_P. A preliminary gate isolation layer 150P may be formed between the spaced apart preliminary word lines WL_P in the recess.

A plurality of back gate electrodes may be formed in the preliminary substrate 300. For example, after patterning the preliminary substrate 300, a preliminary back gate insulating film 182 may be formed in the patterned recess, and then a preliminary back gate electrode BG_P may be formed thereon. Subsequently, a back gate isolation layer 170 may be formed on the preliminary back gate electrode BG_P.

A plurality of active patterns may be formed in the preliminary substrate 300. The region between the recess for forming the word lines in the preliminary substrate 300 and the recess for forming the back gate electrode may be defined as a preliminary active pattern AP_P.

Subsequently, a contact interlayer insulating layer 190 and a landing pad LP may be formed, and a capacitor structure CAP including a first electrode 312, a dielectric film 314, a conductive film 316, and a second electrode 318 may be formed. In addition, an upper interlayer insulating layer 330 covering the capacitor structure CAP, for example, the second electrode 318, and the contact interlayer insulating layer 190 may be formed.

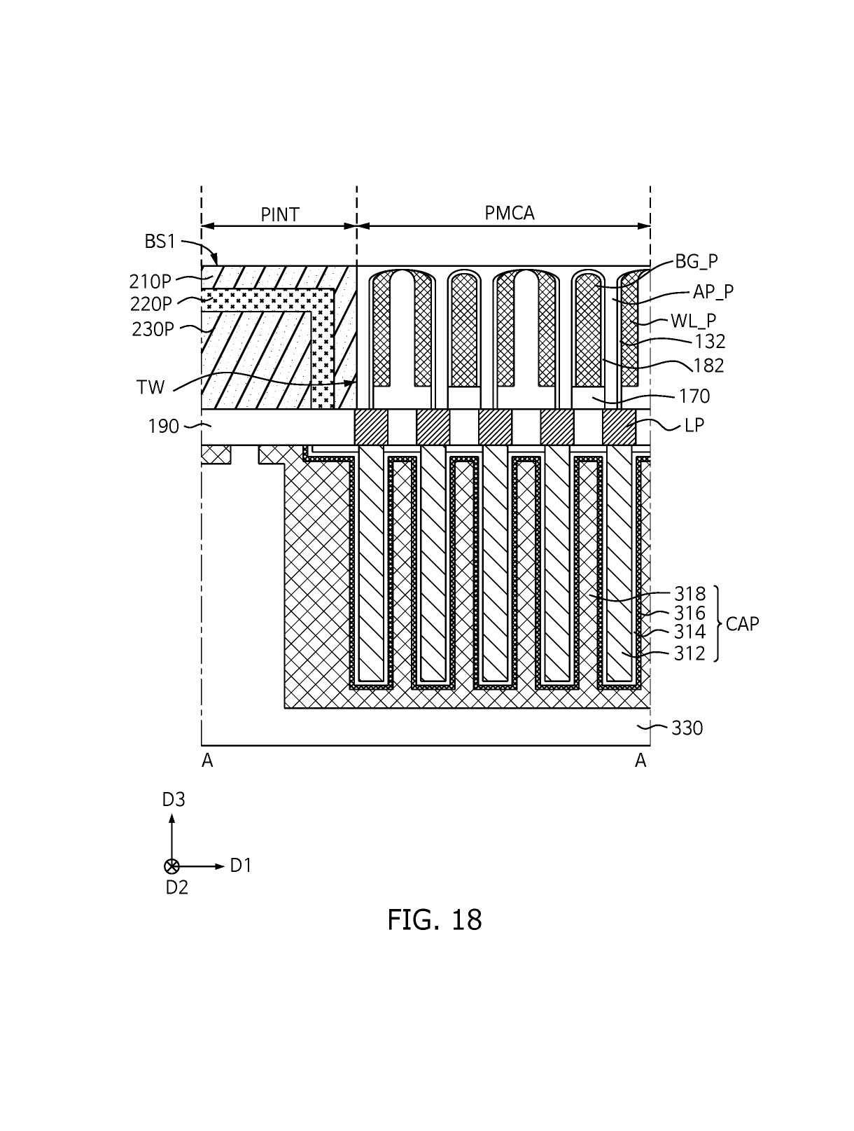

Referring to FIG. 18, after flipping the preliminary substrate 300 so that a lower surface of the preliminary substrate 300 faces upward, the lower surface of the preliminary substrate 300 may be polished. For example, the preliminary substrate 300 may be polished in the preliminary cell region PMCA and the preliminary connection region PINT down to a lower surface BS1 of the first preliminary insulating film 210P. In some embodiments, the preliminary substrate 300 may be polished by a CMP process.

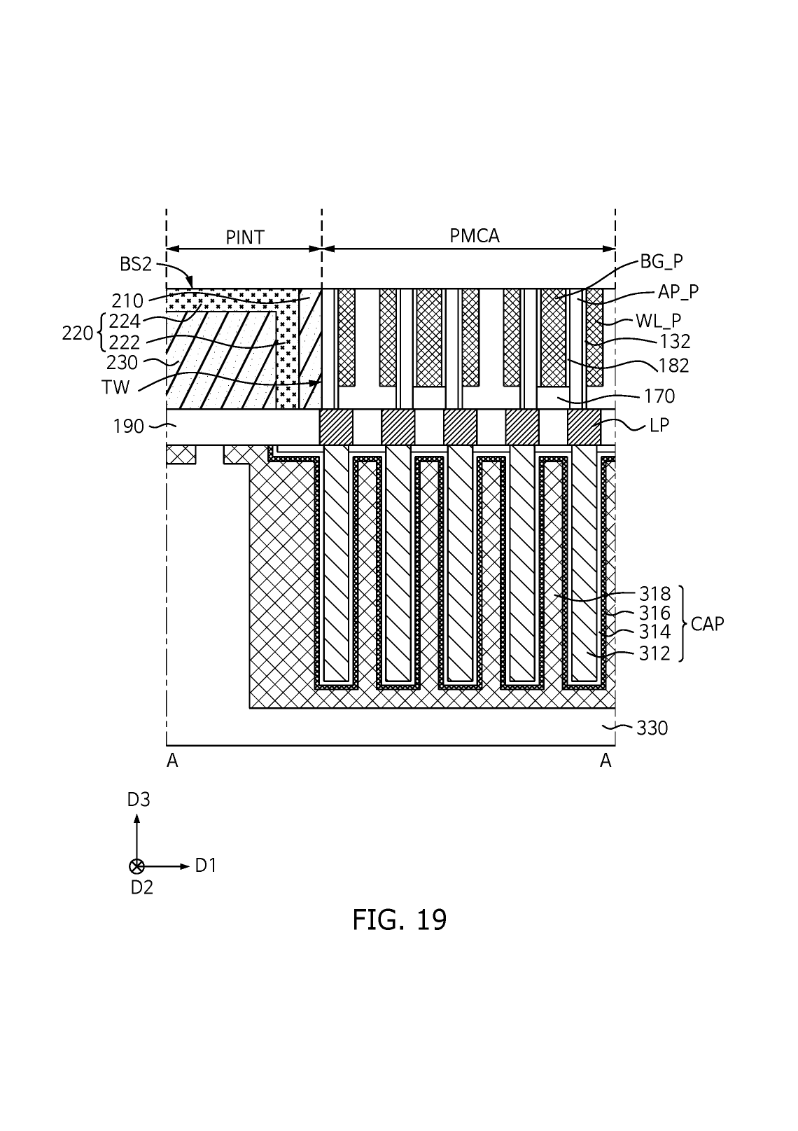

Referring to FIG. 19, the first preliminary insulating film 210 may be polished down to a lower surface BS2 of the second preliminary insulating film 220 in the preliminary connection region PINT. In some embodiments, the first preliminary insulating film 210 may be polished by a CMP process. In this process, the preliminary word line WL_P, the preliminary back gate electrode BG_P, the preliminary active pattern AP_P, and the like may be polished together.

Subsequently, by further patterning the preliminary word line WL_P and the preliminary back gate electrode BG_P and by forming the gate capping layer 140 and the back gate capping layer 160, a plurality of word lines WL, a plurality of back gate electrodes BG, and a plurality of active patterns AP may be formed.

Then, a bit line BL, a landing pad LP connected to the plurality of active patterns AP, and a capacitor structure CAP may be formed, each of which is connected to the plurality of active patterns AP. In this process, the preliminary insulating layer 310 may be formed as the contact interlayer insulating layer 190. Through such a process, the semiconductor memory device described with reference to FIGS. 1 to 11 may be provided.

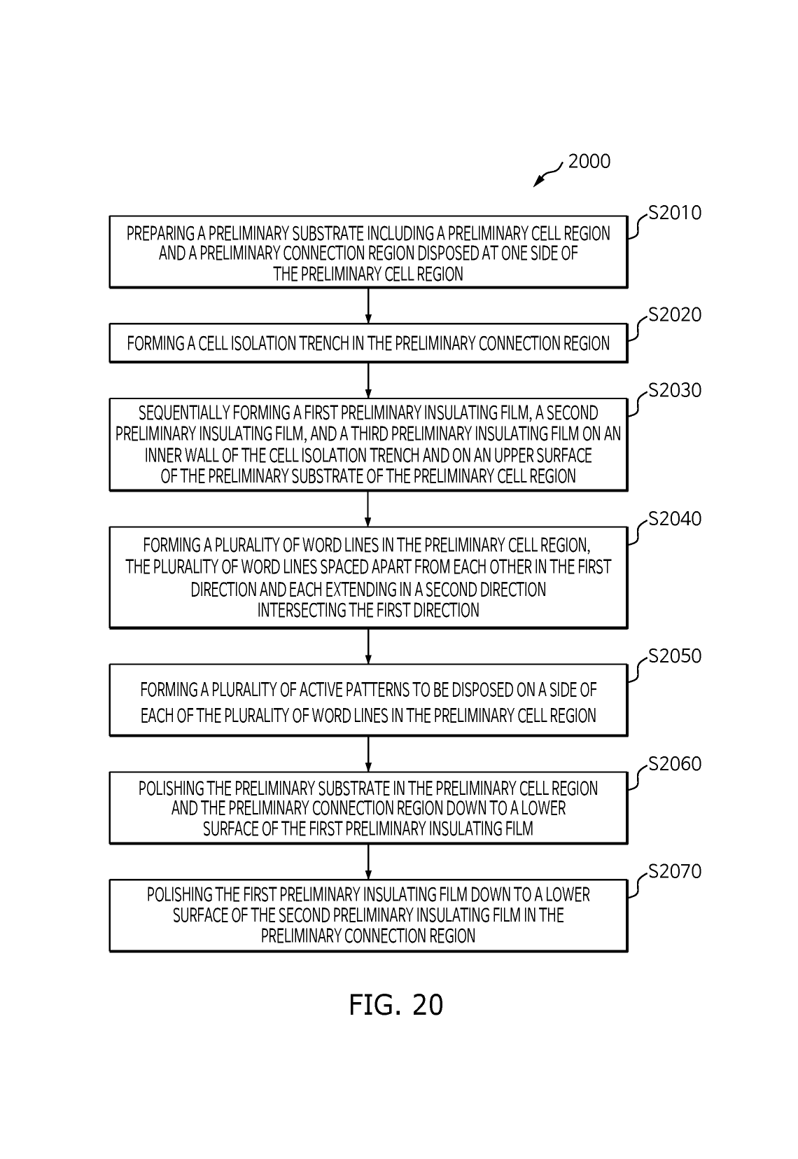

FIG. 20 is a flowchart for describing a method of manufacturing a semiconductor memory device according to some embodiments of the present disclosure.

The method 2000 of manufacturing the semiconductor memory device may begin by preparing a preliminary substrate including a preliminary cell region and a preliminary connection region disposed at one side of the preliminary cell region (S2010). A cell isolation trench may be formed in the preliminary connection region (S2020). A first preliminary insulating film, a second preliminary insulating film, and a third preliminary insulating film may be sequentially formed on an inner wall of the cell isolation trench and on an upper surface of the preliminary substrate of the preliminary cell region (S2030).

A plurality of word lines, spaced apart from adjacent word lines in the first direction and each word line of the plurality of word lines extending in a second direction intersecting the first direction, may be formed in the preliminary cell region (S2040). A plurality of active patterns may be formed to be disposed on a side of each word line of the plurality of word lines in the preliminary cell region (S2050). After forming the active patterns, a landing pad connected to the active patterns may be formed, and a capacitor structure CAP connected to the landing pad may be formed.

The preliminary substrate in the preliminary cell region and the preliminary connection region may be polished down to a lower surface of the first preliminary insulating film (S2060). Then, by polishing the first preliminary insulating film down to a lower surface of the second preliminary insulating film in the preliminary connection region, a cell isolation insulating film may be formed (S2070), which includes a first insulating film, a second insulating film, and a third insulating film that are sequentially disposed on an inner wall of the cell isolation trench.

For example, a cell isolation insulating film may be formed, which includes a first insulating film disposed on an inner wall of the cell isolation trench, a second insulating film including a first portion disposed on one side surface of the first insulating film and a second portion extending in a direction (for example, the first direction and the second direction) parallel to the surface of the preliminary substrate from an end of the first portion, and a third insulating film disposed on the first portion and the second portion.

In some embodiments, the first insulating film and the second insulating film may be formed so that a first width in the first direction of the first insulating film, a second width in the first direction of the first portion, and a third width in a third direction intersecting each of the first direction and the second direction of the second portion are the same as each other.

In some embodiments, the first insulating film and the second insulating film may be formed so that a first width in the first direction of the first insulating film is greater than a second width in the first direction of the first portion and a third width in the third direction of the second portion.

In some embodiments, the first insulating film and the second insulating film may be formed so that a first width in the first direction of the first insulating film is smaller than a second width in the first direction of the first portion and a third width in the third direction of the second portion.

A bit line, contacting lower surfaces of the active pattern and the second insulating film and extending in the first direction, may be formed.

Although the present invention has been described herein with reference to embodiments and drawings, the present invention is not limited thereto, and various modifications and variations are possible within the technical spirit of the present invention and the equivalents of the claims to be described herein, by those having ordinary skill in the art to which the present invention pertains.

In addition, the exemplary embodiments are not exclusive. For example, some exemplary embodiments may include features referred to in one or more drawings, and may additionally include one or more other features referred to in other drawings.

What is claimed is:

1. A semiconductor memory device comprising:
a substrate comprising a cell region and a connection region at one side of the cell region;
a bit line on the substrate and extending in a first direction across the cell region and the connection region;
a word line on the cell region above the bit line and extending in a second direction intersecting the first direction;
a first active pattern on one side surface of the word line on the cell region; and
a cell region isolation layer on the bit line on the connection region,
wherein the first active pattern is an outermost active pattern disposed at an outermost side of the cell region in the first direction,
the cell region isolation layer comprises:
a first insulating film having a first side surface on an outer side surface of the outermost active pattern and extending in the second direction; and
a second insulating film comprising
a first portion on a second side surface of the first insulating film, the first side surface of the first insulating film being opposite the second side surface of the first insulating film, and
a second portion extending in the first direction from a first end of the first portion at the second side surface of the first insulating film, wherein a lower surface of the second portion in a third direction contacts an upper surface of the bit line in the third direction, the third direction intersecting each of the first direction and the second direction.

2. The semiconductor memory device according to claim 1, wherein the first insulating film and the second insulating film comprise different materials.

3. The semiconductor memory device according to claim 1, wherein the cell region isolation layer further comprises a third insulating film on the first portion of the second insulating film and on the second portion of the second insulating film.

4. The semiconductor memory device according to claim 3, wherein the second portion of the second insulating film is between the third insulating film and the bit line in the third direction.

5. The semiconductor memory device according to claim 3, wherein the first portion of the second insulating film is between the first insulating film and the third insulating film in the first direction.

6. The semiconductor memory device according to claim 1, wherein a lower surface of the first active pattern is coplanar with a lower surface of the second insulating film.

7. The semiconductor memory device according to claim 1, further comprising a gate capping layer between the word line and the bit line, wherein a lower surface of the gate capping layer is coplanar with a lower surface of the second insulating film.

8. The semiconductor memory device according to claim 1, wherein a first width in the first direction of the first insulating film, a second width in the first direction of the first portion of the second insulating film, and a third width in the third direction of the second portion of the second insulating film, are the same as each other.

9. The semiconductor memory device according to claim 1, wherein a first width in the first direction of the first insulating film is greater than each of a second width in the first direction of the first portion of the second insulating film and a third width in the third direction of the second portion of the second insulating film.

10. The semiconductor memory device according to claim 1, wherein a first width in the first direction of the first insulating film is smaller than each of a second width in the first direction of the first portion of the second insulating film and a third width in the third direction of the second portion of the second insulating film.

11. The semiconductor memory device according to claim 1, wherein a distance from an upper surface of the first active pattern to a lower surface of the first active pattern is the same as a distance from an upper surface of the first insulating film to a lower surface of the first insulating film.

12. The semiconductor memory device according to claim 1, wherein a distance from an upper surface of the first active pattern to a lower surface of the first active pattern is the same as a distance from an upper surface of the first portion of the second insulating film to a lower surface of the first portion of the second insulating film.

13. The semiconductor memory device according to claim 1, further comprising a second active pattern and a third active pattern spaced apart from each other in the first direction so the second active pattern and the third active pattern face each other,
wherein the semiconductor memory device further comprises:
a back gate electrode between the second active pattern and the third active pattern in the first direction;
a back gate capping layer on a lower surface of the back gate electrode in the third direction; and
a back gate isolation layer on an upper surface of the back gate electrode in the third direction.

14. The semiconductor memory device according to claim 13, wherein a lower surface of the back gate capping layer is coplanar with a lower surface of the second insulating film.

15. The semiconductor memory device according to claim 13, wherein a distance from an upper surface of the back gate isolation layer to a lower surface of the back gate capping layer is the same as a distance from an upper surface of the first insulating film to a lower surface of the first insulating film.

16. A semiconductor memory device comprising:
a substrate comprising a cell region and a connection region at one side of the cell region;
a bit line on the substrate and extending in a first direction across the cell region and the connection region;
a plurality of word lines on the cell region on the bit line, each word line of the plurality of word lines being spaced apart from an adjacent word line in the first direction, the plurality of word lines comprising a first word line and a second word line each extending in a second direction intersecting the first direction;
a plurality of active patterns on the cell region, the plurality of active patterns comprising a first active pattern on a first side surface of the first word line and a second active pattern on a second side surface of the second word line opposite the first side surface of the second word line; and
a cell region isolation layer on the bit line on the connection region,
wherein the cell region isolation layer comprises a first insulating film and a second insulating film that are sequentially on an outer side surface of a third active pattern that is an outermost active pattern among the plurality of active patterns, the outer side surface of the outermost active pattern in the first direction defining a boundary between the cell region and the connection region, and
a lower surface of the second insulating film contacts an upper surface of the bit line in a third direction intersecting each of the first direction and the second direction.

17. The semiconductor memory device according to claim 16, further comprising:
a gate capping layer extending in the first direction on lower surfaces of each of the first word line and the second word line; and
a gate isolation layer between the first word line and the second word line,
wherein the gate isolation layer comprises:
a vertical portion extending in the third direction along a second side surface of the first word line and a first side surface of the second word line; and
a horizontal portion connected to an end of the vertical portion and extending in the first direction on upper surfaces of each of the first word line and the second word line.

18. The semiconductor memory device according to claim 17, wherein a distance from an upper surface of the horizontal portion of the gate isolation layer to a lower surface of the gate capping layer is the same as a distance from an upper surface of the second insulating film to a lower surface of the second insulating film.

19. The semiconductor memory device according to claim 16, wherein a distance from an upper surface of the third active pattern to a lower surface of the third active pattern is the same as a distance from an upper surface of the second insulating film to a lower surface of the second insulating film.

20. A semiconductor memory device comprising:
a substrate comprising a cell region and a connection region at one side of the cell region;
a bit line on the substrate and extending in a first direction across the cell region and the connection region;
a plurality of word lines on the cell region on the bit line, each word line of the plurality of word lines being spaced apart from an adjacent word line in the first direction, the plurality of word lines comprising a first word line and a second word line each extending in a second direction intersecting the first direction;
a plurality of active patterns on the cell region, the plurality of active patterns comprising a first active pattern on a first side surface of the first word line and a second active pattern on a second side surface of the second word line opposite the first side surface of the second word line; and
a cell region isolation layer on the bit line on the connection region,
wherein the cell region isolation layer comprises a first insulating film, a second insulating film, and a third insulating film that are sequentially on an outer side surface of a third active pattern that is an outermost active pattern among the plurality of active patterns, the outer side surface of the outermost active pattern in the first direction defining a boundary between the cell region and the connection region,
wherein the first insulating film and the second insulating film comprise different materials,
wherein the first insulating film and the third insulating film comprise the same material,
wherein a lower surface of the first insulating film and a lower surface of the second insulating film contact an upper surface of the bit line, and
wherein the second insulating film comprises a portion between the third insulating film and the bit line.
